(19) United States
(12) Patent Application Publication
(10) Pub. No.: US 2025/0386506 A1
(43) Pub. Date: Dec. 18, 2025

(54) SEMICONDUCTOR DEVICE, MANUFACTURING METHOD THEREOF AND MEMORY SYSTEM

(71) Applicant: Yangtze Memory Technologies Co., Ltd., Wuhan (CN)

(72) Inventors: Zongliang HUO, Wuhan (CN); Zengpeng ZHANG, Wuhan (CN); Wenbo ZHANG, Wuhan (CN); Sizhe LI, Wuhan (CN); Qianbing XU, Wuhan (CN); Jing GAO, Wuhan (CN)

(21) Appl. No.: 19/238,112

(22) Filed: Jun. 13, 2025

Related U.S. Application Data
(60) Provisional application No. 63/661,018, filed on Jun. 17, 2024.

(30) Foreign Application Priority Data
Jun. 24, 2024 (CN) 202410817457.5

(51) Int. Cl. H10B 43/27; H01L 23/00; H01L 25/00; H01L 25/065; H01L 25/18; H10B 43/35; H10B 80/00

(52) U.S. Cl. CPC H10B 43/27; H01L 24/08; H01L 24/80; H01L 25/0657; H01L 25/18; H01L 25/50; H10B 43/35; H10B 80/00; H01L 2224/08145; H01L 2224/80895; H01L 2224/80896; H01L 2924/1431; H01L 2924/14511

(57) ABSTRACT

According to one aspect of the present disclosure, a semiconductor device is provided. The semiconductor device may include a stacked structure including a plurality of sub-stacked structures stacked along a first direction. A sub-stacked structure of the plurality of sub-stacked structures may include select gate layers and gate layers stacked along the first direction. The semiconductor device may include a contact structure extending in the plurality of sub-stacked structures along the first direction and connected to the gate layers of the plurality of sub-stacked structures. At least one of the select gate layers may be connected to a peripheral circuit structure of the semiconductor device.

### CROSS-REFERENCE TO RELATED APPLICATIONS

This application claims the benefit of priorities to Chinese Application No. 202410817457.5, filed on Jun. 24, 2024, and U.S. Provisional Application No. 63/661,018, filed on Jun. 17, 2024, both of which are hereby incorporated by reference in their entireties.

### TECHNICAL FIELD

The present disclosure relates to the field of semiconductor design and manufacturing, and more particularly, to a semiconductor device, a method of manufacturing a semiconductor device, and a memory system.

### BACKGROUND

With the rise and development of fields of artificial intelligence, big data, Internet of Things, mobile communication, mobile devices, and cloud storage, requirements for storage density of semiconductor devices such as three-dimensional memories have become higher and higher, but it has become more difficult to increase the storage density of semiconductor devices due to factors such as processes, devices and materials.

In addition, with the increase of the number of stacked layers and the increase of the storage density per unit area in a semiconductor device such as a three-dimensional memory, the process operations become complicated and lengthy in the manufacturing process of the semiconductor device, and the manufacturing cost of the semiconductor device is also gradually increased.

Therefore, how to simplify the manufacturing process of the semiconductor device, reduce the manufacturing cost of the semiconductor device and improve the storage density of the semiconductor device while considering the reliability and overall performance of the semiconductor device is an urgent problem to be solved at present.

### SUMMARY

According to one aspect of the present disclosure, a semiconductor device is provided. The semiconductor device may include a stacked structure including a plurality of sub-stacked structures stacked along a first direction. A sub-stacked structure of the plurality of sub-stacked structures may include select gate layers and gate layers stacked along the first direction. The semiconductor device may include a contact structure extending in the plurality of sub-stacked structures along the first direction and connected to the gate layers of the plurality of sub-stacked structures. At least one of the select gate layers may be connected to a peripheral circuit structure of the semiconductor device.

In some implementations, the plurality of sub-stacked structures may include a first sub-stacked structure and remaining sub-stacked structures located on a side of the first sub-stacked structure along the first direction. In some implementations, the contact structure may pass through the remaining sub-stacked structures along the first direction and is connected to gate layers of the first sub-stacked structure.

In some implementations, the stacked structure may include two sides opposite to each other along the first direction, and the semiconductor device may further include a peripheral circuit. In some implementations, the peripheral circuit may be located on at least one of the two sides along the first direction.

In some implementations, the gate layers may extend in the sub-stacked structure along a direction intersecting the first direction. In some implementations, the semiconductor device may further include same-layer dielectric layers disposed in the same layers as the gate layers or the select gate layers. In some implementations, the contact structure may extend along the first direction and passes through a plurality of the same-layer dielectric layers.

In some implementations, the plurality of sub-stacked structures may include a first sub-stacked structure and a second sub-stacked structure located on a side of the first sub-stacked structure along the first direction. In some implementations, the semiconductor device may further include a first semiconductor layer located between the first sub-stacked structure and the second sub-stacked structure along the first direction and extending along a direction intersecting the first direction.

In some implementations, the semiconductor device may include a first region and a second region arranged along a direction intersecting the first direction. In some implementations, the gate layers and the select gate layers may be located in the first region, and same-layer dielectric layers disposed in the same layers as the gate layers or the select gate layers are located in the second region. In some implementations, the first semiconductor layer may be located in the first region and extends along a direction intersecting the first direction.

In some implementations, the select gate layers may be located on a side of the gate layers far away from the first semiconductor layer along the first direction.

In some implementations, the semiconductor device may include a channel structure. In some implementations, the channel structure may include a channel layer extending along the first direction and connected to the first semiconductor layer. In some implementations, the channel structure may include a functional layer surrounding the channel layer. In some implementations, the functional layer may include a first functional layer and a second functional layer. In some implementations, the first functional layer may extend in the first sub-stacked structure along the first direction, and the second functional layer may extend in the second sub-stacked structure along the first direction.

In some implementations, the channel layer and the first semiconductor layer may have the same doping type.

In some implementations, a doping concentration of a conductive impurity of the first semiconductor layer may be greater than a doping concentration of a conductive impurity of the channel layer.

In some implementations, the semiconductor device may include a channel structure extending along the first direction and passing through the select gate layers and the gate layers. In some implementations, the semiconductor device may include a select gate cut structure located in the select gate layers and passing through a portion of the channel structure along the first direction.

In some implementations, the semiconductor device may include second semiconductor layers located on a side of the sub-stacked structures along the first direction and extending along a direction intersecting the first direction. In some implementations, the second semiconductor layers of the plurality of sub-stacked structures may be connected to each other.

In some implementations, the semiconductor device may include a peripheral circuit located on a side of the stacked structure along the first direction. In some implementations, the second semiconductor layer may be located on a side of the sub-stacked structure far away from the peripheral circuit along the first direction.

In some implementations, the select gate layers may be located on a side of the gate layers far away from the second semiconductor layer along the first direction.

In some implementations, the semiconductor device may include a channel structure including sub-channel structures located in different sub-stacked structures. In some implementations, the sub-channel structure may include a sub-channel layer and a sub-functional layer surrounding the sub-channel layer. In some implementations, the sub-channel layer may extend into the second semiconductor layer along the first direction.

In some implementations, the sub-channel layer and the second semiconductor layer may have the same doping type.

In some implementations, a doping concentration of a conductive impurity of the second semiconductor layer may be greater than a doping concentration of a conductive impurity of the sub-channel layer.

In some implementations, the contact structure may include a first section located in the first sub-stacked structure and a second section located in one of the remaining sub-stacked structures. In some implementations, the second section may include a first portion, a second portion and a third portion. In some implementations, the second portion may extend along a direction intersecting the first direction and connected to a gate layer of one of the remaining sub-stacked structures. In some implementations, the first portion and the third portion may be respectively located on two opposite sides of the second portion along the first direction and connected to the second portion.

In some implementations, the second portion may be disposed in the same layer as a gate layer of one of the remaining sub-stacked structures. In some implementations, along a direction intersecting the first direction, a size of the first portion may be greater than a size of the third portion.

In some implementations, the semiconductor device may include a peripheral circuit located on a side of the stacked structure along the first direction. In some implementations, the first portion may be closer to the peripheral circuit structure than the third portion.

In some implementations, the first portion may include a first end and a second end opposite to each other along the first direction, and the second end may be connected to the second portion. In some implementations, along a direction intersecting the first direction, a size of the first end may be greater than a size of the second end.

In some implementations, the third portion may include a third end connected to the second portion. In some implementations, along a direction intersecting the first direction, a size of the second end may be greater than a size of the third end.

In some implementations, a shape of the first portion or the third portion may include a frustum.

In some implementations, the contact structure may include a first section located in the first sub-stacked structure and a third section located in one of the remaining sub-stacked structures. In some implementations, the third section may include a fourth portion and a fifth portion connected to each other. In some implementations, the fourth portion may pass through the remaining sub-stacked structures along a direction intersecting the first direction and may be connected to the first section. In some implementations, the fifth portion may be connected to gate layers of one of the remaining sub-stacked structures.

In some implementations, the fifth portion may have a different thickness along a direction intersecting the first direction. In some implementations, the thickness may be a dimension of the fifth portion along the first direction.

According to another aspect of the present disclosure, a method of manufacturing a semiconductor device is provided. The method may include forming a stacked structure. The stacked structure may include a plurality of sub-stacked structures stacked along a first direction, and a sub-stacked structure of the plurality of sub-stacked structures may include select gate layers and gate layers stacked along the first direction. The method may include forming a contact structure extending in the stacked structure along the first direction and connected to the gate layers of the plurality of sub-stacked structures. The method may include forming a peripheral circuit structure. At least one of the select gate layers may be connected to the peripheral circuit structure.

In some implementations, the forming a contact structure extending in the stacked structure along the first direction and connected to the gate layers of the plurality of sub-stacked structures may include forming a contact hole extending in the stacked structure along the first direction and connected to gate layers of the plurality of sub-stacked structures. In some implementations, the forming a contact structure extending in the stacked structure along the first direction and connected to the gate layers of the plurality of sub-stacked structures may include filling the contact hole to form the contact structure.

In some implementations, the method may include forming the stacked structure on a side of a substrate. In some implementations, the forming the contact hole extending in the stacked structure along the first direction and connected to the gate layers of the plurality of sub-stacked structures may include forming a first opening extending to first same-layer dielectric layers along the first direction. In some implementations, the first same-layer dielectric layers may be located in a sub-stacked structure among the plurality of sub-stacked structures farthest from the substrate and may be disposed in the same layers as gate layers of the farthest sub-stacked structure. In some implementations, the forming the contact hole extending in the stacked structure along the first direction and connected to the gate layers of the plurality of sub-stacked structures may include forming a second opening communicating with the first opening via the first opening. In some implementations, the second opening may extend to second same-layer dielectric layers along the first direction, and the second same-layer dielectric layers may be located in a sub-stacked structure closest to the farthest sub-stacked structure. In some implementations, a first end of the first opening may communicate with a second end of the second opening, and along a direction intersecting the first direction, a size of the first end may be greater than a size of the second end.

In some implementations, the forming the contact hole extending in the stacked structure along the first direction and connected to the gate layers of the plurality of sub-stacked structures may further include removing third same-layer dielectric layers adjacent to the first same-layer dielectric layers via the first opening and the second opening. In some implementations, the third same-layer dielectric layers may be located in the farthest sub-stacked structure and closer to the substrate than the first same-layer dielectric layers. In some implementations, a third opening formed by removing the third same-layer dielectric layers may extend, along a direction intersecting the first direction, to gate layers disposed in the same layers as the third same-layer dielectric layers.

In some implementations, forming the stacked structure may include alternately stacking first dielectric layers and first gate sacrificial layers to form a first sub-stacked structure. In some implementations, forming the stacked structure may include forming a first semiconductor layer on a side of the first sub-stacked structure along the first direction. In some implementations, forming the stacked structure may include alternately stacking second dielectric layers and second gate sacrificial layers on a side of the first semiconductor layer, along the first direction, to form a second sub-stacked structure. In some implementations, forming the stacked structure may include replacing portions of the first gate sacrificial layers and portions of the second gate sacrificial layers with the gate layers.

In some implementations, forming a channel structure. In some implementations, the forming the channel structure may include forming a channel hole extending in the first sub-stacked structure and the second sub-stacked structure along the first direction. In some implementations, the channel hole may expose a portion of the first semiconductor layer. In some implementations, the forming the channel structure may include forming an initial functional layer in the channel hole. In some implementations, the forming the channel structure may include removing a portion of the initial functional layer on an exposed first semiconductor layer to form a first functional layer and a second functional layer. In some implementations, the first functional layer may extend in the first sub-stacked structure along the first direction, and the second functional layer may extend in the second sub-stacked structure along the first direction. In some implementations, the forming the channel structure may include forming a channel layer on surfaces of the first functional layer, the first semiconductor layer and the second functional layer.

According to a further aspect of the present disclosure, a memory system is provided. The memory system may include at least one semiconductor device. The semiconductor device may include a stacked structure including a plurality of sub-stacked structures stacked along a first direction. A sub-stacked structure of the plurality of sub-stacked structures may include select gate layers and gate layers stacked along the first direction. The semiconductor device may include a contact structure extending in the plurality of sub-stacked structures along the first direction and connected to the gate layers of the plurality of sub-stacked structures. At least one of the select gate layers may be connected to a peripheral circuit structure of the semiconductor device. The memory system may include a controller coupled to the semiconductor device and configured to control the semiconductor device to store data.

### BRIEF DESCRIPTION OF DRAWINGS

Other features, objects, and benefits of the present disclosure will become more apparent upon reading the detailed description of non-limiting implementations made with reference to the following drawings. In the drawings:

FIG. 1 is a schematic cross-sectional view of a semiconductor device according to an implementation of the present disclosure;

FIG. 2 is a schematic cross-sectional view of a semiconductor device according to another implementation of the present disclosure;

FIG. 3 is a schematic cross-sectional view of a semiconductor device according to an implementation of the present disclosure;

FIG. 4 is a schematic partial cross-sectional view of a semiconductor device according to an implementation of the present disclosure;

FIG. 5 is a schematic cross-sectional view of a contact structure according to an implementation of the present disclosure;

FIG. 6 is a schematic partial cross-sectional view of a semiconductor device according to an implementation of the present disclosure;

FIG. 7 is a flowchart of a method of manufacturing a semiconductor device according to an implementation of the present disclosure;

FIGS. 8-25 are schematic process diagrams of a method of manufacturing a semiconductor device according to an implementation of the present disclosure; and

FIG. 26 is a schematic structural diagram of a memory system according to an implementation of this application.

### DETAILED DESCRIPTION

The following describes the present disclosure in detail with reference to the accompanying drawings, and the exemplary implementations mentioned herein are merely used to explain the present disclosure, and are not intended to limit the scope of the present disclosure. Throughout the specification, like reference numerals refer to like elements.

In the drawings, the thickness, size and shape of the components have been slightly adjusted for ease of illustration. The drawings are merely examples and are not strictly drawn to scale. As used herein, the terms “about”, “approximately”, and similar terms are used to represent an approximation, but are not used to represent a degree, and are intended to illustrate inherent deviations in measured or calculated values that will be recognized by one of ordinary skill in the art.

It should also be understood that the expression “and/or” includes any and all combinations of one or more of the associated listed items. References such as “comprising”, “including”, “comprise”, “include”, and/or “having” which are open rather than closed in this specification, indicate the presence of stated features, elements, and/or components, but do not preclude the presence or addition of one or more other features, elements, components, and/or combinations thereof. Furthermore, when an expression such as “at least one of” appears after the list of listed features, it modifies the entire list of features, rather than merely modifying individual elements in the list. When describing implementations of the present disclosure, “may” is used to mean “one or more implementations of the present disclosure”. Also, the term “exemplary” is intended to refer to an example or illustration.

In addition, when the expressions “connected”, “covered” and/or “formed on” are used in the present disclosure, it may mean that the corresponding components are in direct contact or indirect contact, unless explicitly defined otherwise or can be derived from the context. In addition, “connected” may also represent an electrical connection, such as a circuit conduction connection state in an operating state of a semiconductor device.

Unless otherwise defined, all phrases (including technical and scientific terms) used herein have the same meaning as commonly understood by one of ordinary skill in the art to which the present disclosure belongs. Furthermore, unless explicitly stated in this application, words defined in commonly used dictionaries should be interpreted as having a meaning consistent with their meaning in the context of the related art, and should not be interpreted in an idealized or overly formal sense.

It should be noted that, in the case of no conflict, the implementations in the present disclosure and the features in the implementations may be combined with each other. In addition, unless explicitly defined or contradicted by context, specific operations included in the methods described in the present disclosure are not necessarily limited to the described order, but may be performed in any order or in parallel. The present disclosure will be described in detail below with reference to the accompanying drawings in combination with implementations.

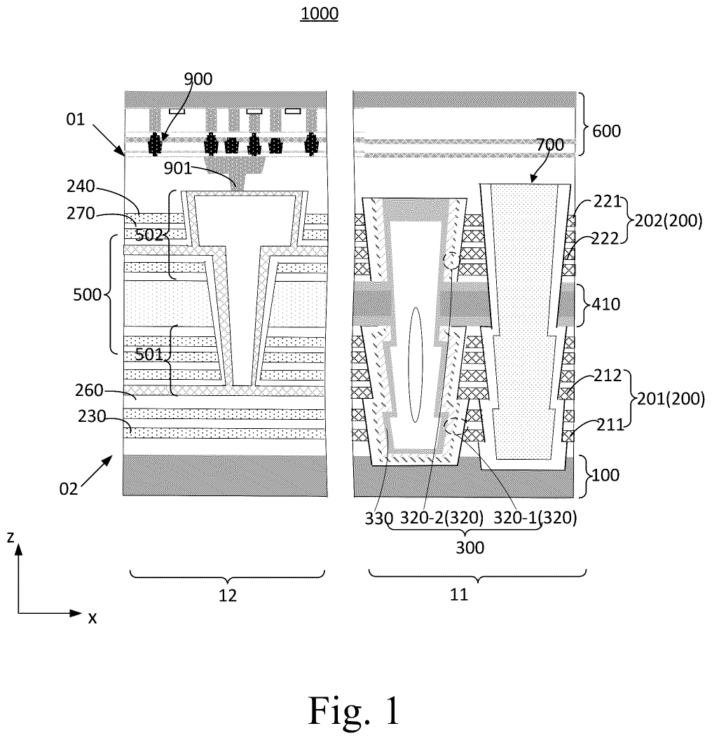

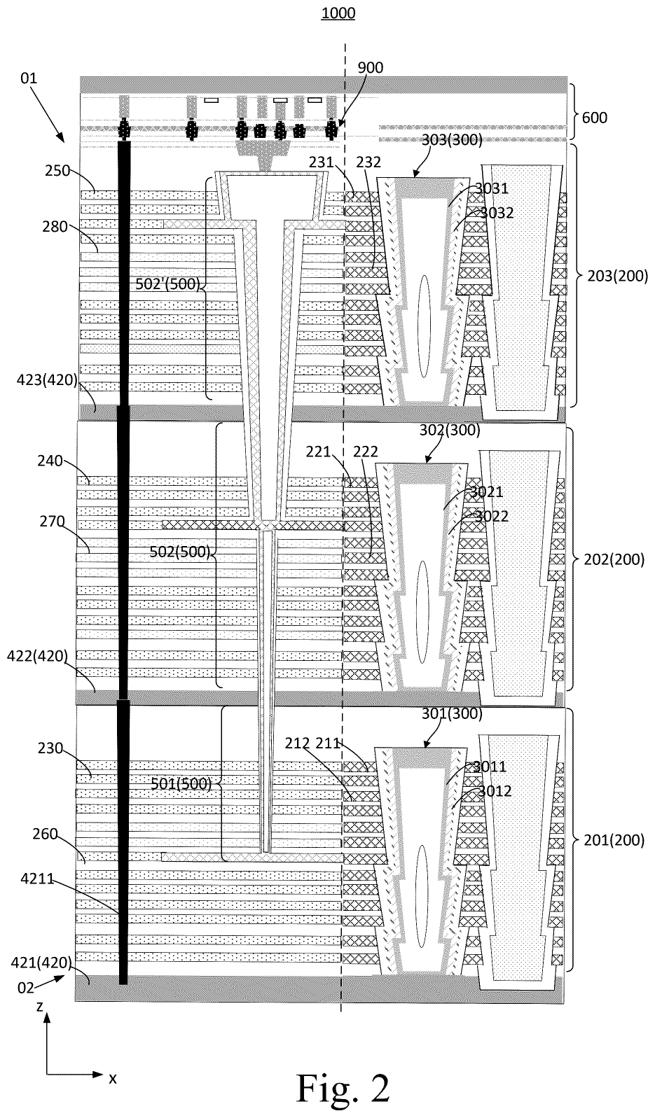

FIG. 1 is a schematic cross-sectional view of a semiconductor device 1000 according to an implementation of the present disclosure. FIG. 2 is a schematic cross-sectional view of a semiconductor device 1000 according to another implementation of the present disclosure.

As shown in FIGS. 1-2, the semiconductor device 1000 includes a stacked structure 200 and a contact structure 500. The stacked structure 200 may include a plurality of sub-stacked structures stacked along a first direction (z direction), such as a first sub-stacked structure 201, a second sub-stacked structure 202 and a third sub-stacked structure 203. The sub-stacked structure may include select gate layers and gate layers stacked along the first direction. For example, the first sub-stacked structure 201 may include first select gate layers 211 and first gate layers 212 stacked along the z direction; the second sub-stacked structure 202 may include second select gate layers 221 and second gate layers 222 stacked along the z direction; and the third sub-stacked structure 203 may include third select gate layers 231 and third gate layers 232 stacked along the z direction. The contact structure 500 extends in the plurality of sub-stacked structures along the z direction and is connected to the gate layers of the plurality of sub-stacked structures. For example, the contact structure 500 shown in FIG. 1 extends in the first sub-stacked structure 201 and the second sub-stacked structure 202 along the z direction, and is connected to the first gate layers 212 of the first sub-stacked structure 201 and the second gate layers 222 of the second sub-stacked structure 202; and the contact structure 500 shown in FIG. 2 extends in the first sub-stacked structure 201, the second sub-stacked structure 202 and the third sub-stacked structure 203 along the z direction, and is connected to the first gate layers 212 of the first sub-stacked structure 201, the second gate layers 222 of the second sub-stacked structure 202, and the third gate layers 232 of the third sub-stacked structure 203. At least one of the plurality of select gate layers is connected to a peripheral circuit structure 600 of the semiconductor device 1000, for example, at least one of the first select gate layers 211 of the first sub-stacked structure 201, the second select gate layers 221 of the second sub-stacked structure 202, and the third select gate layers 231 of the third sub-stacked structure 203 may be connected to the peripheral circuit structure 600.

According to a semiconductor device provided by at least one implementation of the present disclosure, a stacked structure of the semiconductor device may include a plurality of sub-stacked structures stacked along the first direction, where the contact structure extends along the first direction and is connected to gate layers of the plurality of sub-stacked structures. In addition, the semiconductor device may control different sub-stacked structures to work independently by select gate layers connected to a peripheral circuit. Therefore, this can allow the plurality of sub-stacked structures, on the basis of realizing independent operation, to be connected to the peripheral circuit by the same contact structure, thus, the number of contact structures in the semiconductor device is reduced, and the storage density of the semiconductor device is improved, meanwhile the manufacturing process of the contact structures is simplified, and the manufacturing cost of the semiconductor device is reduced.

Taking a three-dimensional memory as an example, some semiconductor devices include a stacked structure formed by alternately stacked gate layers and dielectric layers, where a word line contact located in a step region of the stacked structure can realize connection between the gate layers and an external circuit.

However, with the increase of the number of stacked layers, it is necessary to form word line contacts in the step region through multiple processes such as photolithography and etching to form staircase morphology of steps, which greatly increases manufacturing cost of the semiconductor device; in addition, the larger the number of steps, the larger the area of the step region to be formed, which is not conducive to improving the integration level of the semiconductor device. In addition, as the number of stacked layers increases, the warpage of the wafer is increased, and alignment with the step surface in the step region is more difficult when word line contacts are formed.

For the semiconductor device provided by implementations of the disclosure, the steps and the word line contacts corresponding to the steps do not need to be formed therein, and gate layers located at different stack heights can be connected to the external circuit through a plurality of contact structures with different extension lengths, so that the manufacturing process of the semiconductor device is simplified and the manufacturing cost is reduced, the size of the semiconductor device is reduced, and the storage density per unit area, reliability and overall performance of the semiconductor device are improved.

Specifically, the stacked structure 200 may include a first sub-stacked structure 201 and remaining sub-stacked structures located on a side of the first sub-stacked structure 201 along the z direction, for example, a second sub-stacked structure 202, a third sub-stacked structure 203, and the like.

In an example, the first sub-stacked structure 201 may include a plurality of first gate layers 212 stacked along the z direction; the second sub-stacked structure 202 may include a plurality of second gate layers 222 stacked along the z direction; and the third sub-stacked structure 203 may include a plurality of third gate layers 232 stacked along the z direction.

The gate layers may each include a conductive material, such as one or more of tungsten (W), cobalt (Co), copper (Cu), aluminum (Al), doped crystalline silicon, or silicide. In addition, the gate layers located in different sub-stacked structures may include conductive material layers of the same material, or may include conductive material layers of different materials, which is not limited in the present disclosure. In an example, the number of gate layers included in different sub-stacked structures may be the same or different. In addition, the number of the gate layers included in different sub-stacked structures is not limited to the number shown in the figure, and may be further set as required.

The semiconductor device 1000 may include a memory array, where the memory array may include a channel structure 300 and a contact structure 500. The peripheral circuit structure 600 may be configured as an operation circuit. In an example, the peripheral circuit structure 600 may include any suitable digital, analog, and/or mixed signal circuit for facilitating operation of a memory array in semiconductor device 1000. For example, the peripheral circuit structure 600 may include one or more of a page buffer, a decoder (e.g., a row decoder and a column decoder), a sense structure (e.g., a bit line sense amplification structure), a driver structure (e.g., a word line driver structure), an input/output circuit, a charge pump, a voltage source or generator, a current or voltage reference, any portion (e.g., a sub-circuit) of the functional circuits described above, or any active or passive component of the circuit (e.g., a transistor, a diode, a resistor, or a capacitor), which is not limited herein.

In addition, in some implementations of the present disclosure, the peripheral circuit structure 600 may be connected to the stacked structure 200 by bonding. In this implementation, the semiconductor device 1000 may further include a wafer connection structure 900 extending through a bonding layer along the z direction. In an example, the wafer connection structure 900 may include vertical interconnect accesses. By adopting the vertical interconnection access, the input/output transfer speed between two bonded wafers can be improved, and is beneficial for connecting the wafer connection structure 900 between the two bonded wafers with connection portion 901 of the contact structure 500.

It should be noted that, in the drawings herein, structures, numbers and positions of the peripheral circuit and the interconnection structure (for example, interconnection layers, interconnection vias and interconnection lines) are exemplarily shown, but it may be understood that the peripheral circuit and interconnection structure shown in the drawings herein and related content are merely shown for ease of illustration, and the present disclosure is not limited thereto. Those skilled in the art can adjust the situations of the peripheral circuit and the interconnection structure according to the idea of the present disclosure to achieve the same technical effect.

In some implementations of the present disclosure, the stacked structure 200 may include two sides opposite to each other along the z direction, for example, a first side 01 and a second side 02. In an example, the peripheral circuit structure 600 may be disposed on at least one of the first side 01 and the second side 02. In addition, the peripheral circuit structure 600 may also be disposed on other portions of the semiconductor device 1000, which is not limited in the present disclosure.

In an example, the contact structure 500 may pass through the remaining sub-stacked structures along the z direction and be connected to the first gate layers 212 of the first sub-stacked structure 201. In other words, taking the peripheral circuit structure 600 located on the first side 01 as an example, the contact structure 500 connected to the peripheral circuit structure 600 may extend from the first side 01 along the z direction, pass through a plurality of remaining sub-stacked structures, and be connected to the first gate layers 212 of the first sub-stacked structure 201, where the first sub-stacked structure 201 is further away from the peripheral circuit structure 600 along the z direction than the remaining sub-stacked structures.

Additionally, the gate layer may extend in the sub-stacked structure along a direction intersecting the z direction (e.g., x direction). For example, the first gate layer 212 may extend in the first sub-stacked structure 201 along a direction intersecting the z direction; the second gate layer 222 may extend in the second sub-stacked structure 202 along a direction intersecting the z direction; and the third gate layer 232 may extend in the third sub-stacked structure 203 along a direction intersecting the z direction, etc.

Similarly, the select gate layer may also extend in the sub-stacked structure along a direction intersecting the z direction (e.g., x direction). For example, the first select gate layer 211 may extend in the first sub-stacked structure 201 along a direction intersecting the z direction; the second select gate layer 221 may extend in the second sub-stacked structure 202 along a direction intersecting the z direction; and the third select gate layer 231 may extend in the third sub-stacked structure 203 along a direction intersecting the z direction, etc.

In an example, each of the select gate layers may include a conductive material, such as one or more of tungsten (W), cobalt (Co), copper (Cu), aluminum (Al), doped crystalline silicon, or silicide. In addition, the select gate layers in different sub-stacked structures may include conductive material layers of the same material, or may include conductive material layers of different materials, which is not limited in the present disclosure. In an example, the number of the select gate layers included in the sub-stacked structure may be greater than or equal to 1. In addition, the number of select gate layers included in different sub-stacked structures may be the same or different.

In addition, the semiconductor device 1000 may further include dielectric layers disposed in the same layer as the gate layers or the select gate layers. For example, first same-layer dielectric layers 230 disposed in the same layer as the first select gate layers 211 and the first gate layers 212; second same-layer dielectric layers 240 disposed in the same layer as the second select gate layers 221 and the second gate layers 222; and third same-layer dielectric layers 250 disposed in the same layer as the third select gate layers 231 and the third gate layers 232. In an example, the contact structure 500 extends along the z direction and passes through a plurality of same-layer dielectric layers. For example, the contact structure 500 may pass through the plurality of third same-layer dielectric layers 250, the plurality of second same-layer dielectric layers 240, and at least one first same-layer dielectric layer 230 along the z direction.

In other words, the stacked structure 200 may include isolation dielectric layers and composite layers stacked alternately. Taking the first sub-stacked structure 201 as an example, the composite layer may include a first gate layer 212 and a first same-layer dielectric layer 230 disposed in the same layer, and in addition, the composite layer may also include a first select gate layer 211 and a first same-layer dielectric layer 230 disposed in the same layer. The first gate layer 212 and the first same-layer dielectric layer 230 may be connected to each other and arranged in an x-y plane intersecting the z direction, and the first gate layer 212 extends from the first region 11 of the stacked structure 200 to the second region 12 along the x-direction and is connected to the first same-layer dielectric layer 230 disposed in the same layer, where the first same-layer dielectric layer 230 is located in the second region 12. In addition, the first select gate layer 211 and the first same-layer dielectric layer 230 may also be connected to each other and arranged in the x-y plane, and the first select gate layer 211 extends from the first region 11 of the stacked structure 200 to the second region 12 in the x-direction and is connected to the first same-layer dielectric layer 230 disposed in the same layer, where the first same-layer dielectric layer 230 is located in the second region 12.

In the first sub-stacked structure 201, the composite layers may be alternately stacked with first dielectric layers 260 along the z direction. Similarly, the composite layer of the second sub-stacked structure 202 may include a second gate layer 222 and a second same-layer dielectric layer 240 disposed in the same layer, and a second select gate layer 221 and a second same-layer dielectric layer 240 disposed in the same layer. In the second sub-stacked structure 202, the composite layers and the second dielectric layers 270 may be alternately stacked along the z direction; and the composite layer of the third sub-stacked structure 203 may include a third gate layer 232 and a third same-layer dielectric layer 250 disposed in the same layer, and a third select gate layer 231 and a third same-layer dielectric layer 250 disposed in the same layer. In the third sub-stacked structure 203, the composite layers may be alternately stacked with third isolation dielectric layers 280 along the z direction. That is, in some implementations of the present disclosure, the gate layers and the select gate layers may be located in the first region 11, and the same-layer dielectric layers disposed in the same layers as the gate layers or the select gate layers may be located in the second region 12. Thus, the second region 12 includes a stacked insulating dielectric material layer formed by the same-layer dielectric layers and the isolation dielectric layers stacked alternately.

In an example, the same-layer dielectric layer may include any suitable insulating dielectric material layer. Exemplarily, the same-layer dielectric layer may include an insulating dielectric material layer such as silicon nitride. In addition, the same-layer dielectric layers located in different sub-stacked structures may include insulating dielectric material layers of the same material, or may include insulating dielectric material layers of different materials, which is not limited in the present disclosure. Additionally, the isolation dielectric layer may include any suitable insulating dielectric material layer. Exemplarily, the isolation dielectric layer may include an insulating dielectric material layer such as silicon oxide. The isolation dielectric layers located in different sub-stacked structures may include insulating dielectric material layers of the same material, or may include insulating dielectric material layers of different materials, which is not limited in the present disclosure.

Therefore, the contact structure provided by implementations of the present disclosure extends along the z direction, passes through a plurality of isolation dielectric layers and the same-layer dielectric layer, and is connected to gate layers in different sub-stacked structures. Therefore, the contact structure is located in stacked insulating dielectric material layers, the probability of short circuit connection of different gate layers due to the contact structure is reduced while achieving effective connection between the contact structures and the corresponding gate layers.

In addition, referring to FIG. 1, in some implementations of the present disclosure, the semiconductor device 1000 may further include a semiconductor layer 410, and the semiconductor layer 410 is located between the first sub-stacked structure 201 and the second sub-stacked structure 202 along the z direction and extends along a direction intersecting the z direction (e.g., x direction). In an example, the semiconductor layer 410 may be located only in the first region 11. In an example, the semiconductor layer 410 may also extend from the first region 11 into the second region 12 along the x direction, which is not limited in the present disclosure.

In an example, a select gate layer is located on a side of a plurality of gate layers away from the semiconductor layer 410 along the z direction. For example, the first select gate layer 211 is located on a side of the plurality of first gate layers 212 away from the semiconductor layer 410 along the z direction; and the second select gate layer 221 is located on a side of the plurality of second gate layers 222 away from the semiconductor layer 410 along the z direction. In other words, each of the sub-stacked structures may include “top” and “bottom” disposed opposite to each other along the z direction, where the semiconductor layer 410 may be located between the “top” of the first sub-stacked structure 201 and the “bottom” of the second sub-stacked structure 202, the first select gate layer 211 may be located at the “bottom” of the first sub-stacked structure 201, and the second select gate layer 221 may be located at the “top” of the second sub-stacked structure 202. It should be noted that “top” and “bottom” mentioned above are intended to indicate that the above two ends are different ends disposed along the z direction, and may also be referred to as “first end” and “second end”, which are not limited in this application.

In addition, the semiconductor device 1000 may further include a channel structure 300 including a channel layer 330 and a functional layer 320 surrounding the channel layer 330. The channel layer 330 extends along the z direction and is connected to the semiconductor layer 410. The functional layer 320 include a first functional layer 320-1 extending along the z direction in the first sub-stacked structure 201 and a second functional layer 320-2 extending along the z direction in the second sub-stacked structure 202.

Taking the three-dimensional memory as an example, a channel layer extends in a stacked structure along a stacking direction, and the distance between a source layer and a drain layer located on both sides of the channel layer along the stacking direction is elongated with the increase of the number of stacked layers in the stacked structure, which leads to the decrease of the open current of the channel during the operation of the semiconductor device and affects the execution of the read operation of the semiconductor device.

In the above implementation of the present disclosure, the semiconductor layer 410 is located between the first sub-stacked structure 201 and the second sub-stacked structure 202 and connected to the channel layer 330, so that the portion of the channel layer 330 located in the first sub-stacked structure 201 (hereinafter referred to as a first channel layer) and the portion of the channel layer 330 located in the second sub-stacked structure 202 (hereinafter referred to as a second channel layer) are connected in parallel. In other words, the semiconductor layer 410 may serve as a drain (or a source) of the first channel layer and the second channel layer in the upper and lower sub-stacked structures (the first sub-stacked structure 201 and the second sub-stacked structure 202), and by connecting the first channel layer and the second channel layer in the upper and lower stacked structures in parallel, the open channel current of the semiconductor device may be improved.

In an example, both the first functional layer 320-1 and the second functional layer 320-2 may include a blocking layer, a charge trapping layer and a tunneling layer. For example, the first functional layer 320-1 and the second functional layer 320-2 may each include a blocking layer formed on an inner wall of a channel hole (not shown) to block charge flow out; a charge trapping layer formed on a surface of the blocking layer to store charge during operation of the semiconductor device; and a tunneling layer formed on a surface of the charge trapping layer.

In some implementations, both the first functional layer 320-1 and the second functional layer 320-2 may include oxide-nitride-oxides (ONO) structures. However, in some other implementations, the first functional layer 320-1 and the second functional layer 320-2 may also have structures different from the ONO configuration. The channel layer 330 may be formed on a surface of the tunneling layer and can be configured to transport a desired charge (electrons or holes).

In an example, the channel layer 330 may be made of a semiconductor material such as polycrystalline silicon or monocrystalline silicon, and may have conductive impurities. For example, the channel layer 330 may include an N-type doped or P-type doped polysilicon layer. The channel layer 330 may have a cylindrical or pillar shape extending along the z direction.

The semiconductor layer 410 may also be made of a semiconductor material such as polysilicon or monocrystalline silicon, and may have conductive impurities. In an example, the doping types of the channel layer 330 and the semiconductor layer 410 may be the same. In addition, doping concentration of conductive impurities of the semiconductor layer 410 may be greater than doping concentration of conductive impurities of the channel layer 330. In other words, the drain or source having a relatively high conductive impurity doping concentration can improve the mobility of electrons or holes in the channel, thereby improving the response speed of the semiconductor device.

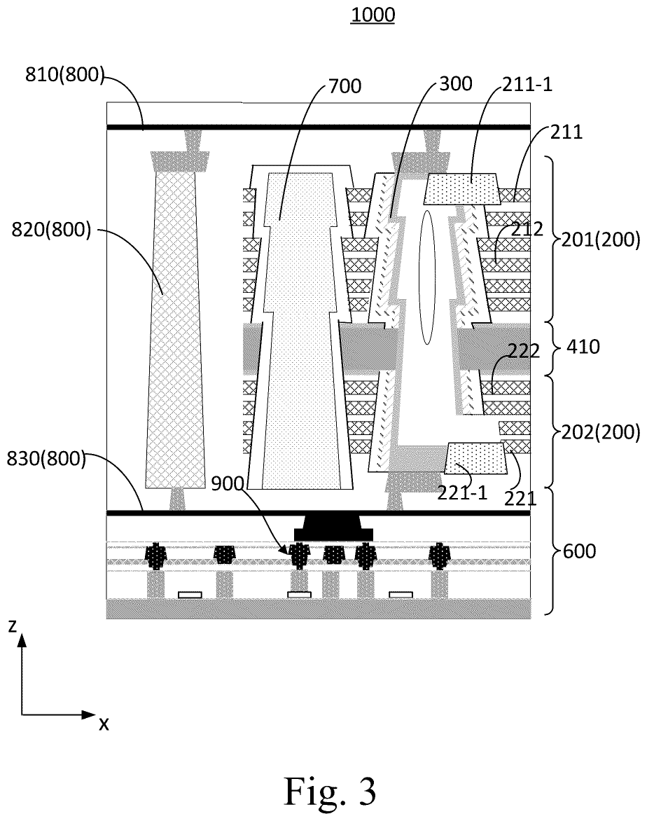

FIG. 3 is a schematic cross-sectional view of a semiconductor device 1000 according to an implementation of the present disclosure. As shown in FIG. 3, the semiconductor layer 410 is located between the first sub-stacked structure 201 and the second sub-stacked structure 202, and is connected to the channel layer 330, so as to serve as a common drain (or a common source) of a portion of the channel layer 330 located in the first sub-stacked structure 201 and a portion of the channel layer 330 located in the second sub-stacked structure 202. In addition, the channel layer 330 may further include two ends opposite to each other along the z direction, the semiconductor device 1000 may further include a channel connection structure 800, and the channel connection structure 800 may be connected to the two ends of the channel layer 330 opposite to each other along the z direction, so that the portion of the channel layer 330 located in the first sub-stacked structure 201 and the portion of the channel layer 330 located in the second sub-stacked structure 202 may be connected together again to form a common source (or a common drain), thereby achieving parallel connection of the portion of the channel layer 330 located in the first sub-stacked structure 201 and the portion of the channel layer 330 located in the second sub-stacked structure 202.

Specifically, the channel connection structure 800 may include a first channel connection structure 810, a second channel connection structure 820, and a third channel connection structure 830 connected to each other. Both the first channel connection structure 810 and the third channel connection structure 830 may extend along a direction intersecting the z direction (e.g., the x direction), and connect an end of the channel layer 330 and the second channel connection structure 820.

In an example, each of the first channel connection structure 810, the second channel connection structure 820 and the third channel connection structure 830 may include a conductive material, such as one or more of tungsten (W), cobalt (Co), copper (Cu), aluminum (Al), doped crystalline silicon, or silicide.

In addition, in some implementations of the present disclosure, the semiconductor device 1000 may further include a select gate cut structure located in select gate layers and passing through a portion of the channel structure 300 along the z direction. For example, the channel structure 300 extends along the z direction and passes through the first select gate layers 211, the first gate layers 212, the second gate layers 222 and the second select gate layers 221. The select gate cut structure may include a first select gate cut structure 211-1 located in the first sub-stacked structure 201 and a second select gate cut structure 221-1 located in the second sub-stacked structure 202, where the first select gate cut structure 211-1 is located in the first select gate layer 211 and passes through a portion of the channel structure 300 along the z direction, and the second select gate cut structure 221-1 is located in the second select gate layer 221 and passes through a portion of the channel structure 300 along the z direction. The select gate cut structure passes through a portion of the channel structure along the z direction, so that the arrangement density of the channel structure can be improved, and the improvement of the unit storage density per unit in the semiconductor device is facilitated.

Referring again to FIG. 1 and FIG. 3, in some implementations of the present disclosure, the semiconductor device 1000 may further include a gate line isolation structure 700, and the gate line isolation structure 700 may pass through the stacked structure 200 along the z direction. In addition, the gate line isolation structure 700 may also extend in the stacked structure 200 along y direction intersecting both the x direction and the z direction.

In an example, the gate line isolation structure 700 may include a gate line isolation layer and a gate line filling layer surrounded by the gate line isolation layer. In an example, a material of the gate line isolation layer may include at least one of a high-k dielectric layer and an insulating dielectric material layer such as silicon oxide layer. In addition, the material of the gate line filling layer may include at least one of a semiconductor material such as polysilicon and an insulating dielectric material layer such as silicon oxide, silicon nitride and silicon oxynitride. In an example, the material of the gate line filling layer may further include a conductive material layer. The present disclosure does not limit the inner filling material of the gate line isolation structure 700.

In addition, referring to FIG. 2, in some implementations of the present disclosure, the semiconductor device 1000 may further include second semiconductor layers 420, the second semiconductor layer 420 may be located on a side of the sub-stacked structure along the z direction and extend along a direction intersecting the z direction (e.g., the x direction), and the second semiconductor layers 420 of a plurality of sub-stacked structures may be connected to each other. For example, the plurality of second semiconductor layers 420 may include: a first sub-semiconductor layer 421 located on a side of the first sub-stacked structure 201, a second sub-semiconductor layer 422 located on a side of the second sub-stacked structure 202; and a third sub-semiconductor layer 423 and the like located on a side of the third sub-stacked structure 203, where the first sub-semiconductor layer 421, the second sub-semiconductor layer 422 and the third sub-semiconductor layer 423 may be connected to each other through the connecting portion 4211.

In an example, the connection portion 4211 may include a plurality of portions located in different sub-stacked structures, and the plurality of portions may each include a conductive material, such as one or more of tungsten (W), cobalt (Co), copper (Cu), aluminum (Al), doped crystalline silicon, or silicide.

Further, the channel structure 300 may include sub-channel structures located in different sub-stacked structures. For example, the channel structure 300 may include a first sub-channel structure 301 located in the first sub-stacked structure 201, a second sub-channel structure 302 located in the second sub-stacked structure 202, and a third sub-channel structure 303 located in the third sub-stacked structure 203.

In an example, the sub-channel structure may include a sub-channel layer and a sub-functional layer surrounding the sub-channel layer. For example, the first sub-channel structure 301 includes a first sub-channel layer 3011 and a first sub-functional layer 3012 surrounding the first sub-channel layer 3011; the second sub-channel structure 302 includes a second sub-channel layer 3021 and a second sub-functional layer 3022 surrounding the second sub-channel layer 3021; and the third sub-channel structure 303 includes a third sub-channel layer 3031 and a third sub-functional layer 3032 surrounding the third sub-channel layer 3031. The sub-channel layer may extend into the second semiconductor layer along the z direction. For example, the first sub-channel layer 3011 extends into the first sub-semiconductor layer 421 along the z direction; the second sub-channel layer 3021 extends into the second sub-semiconductor layer 422 along the z direction; and the third sub-channel layer 3031 extends into the third sub-semiconductor layer 423 along the z direction.

In this implementation of the present disclosure, the sub-channel layers located in different sub-stacked structures respectively extend into different sub-semiconductor layers, and a plurality of different sub-semiconductor layers may be connected to each other through a connecting portion. Therefore, the plurality of second semiconductor layers may serve as drains (or sources) of the sub-channel layers in the sub-stacked structure, so that the sub-channel layers located in different sub-stacked structures are connected in parallel, which may improve the channel open circuit current of the semiconductor device.

In an example, each sub-functional layer may include a blocking layer, a charge trapping layer and a tunneling layer. For example, the first sub-functional layer 3012, the second sub-functional layer 3022 and the third sub-functional layer 3032 may each include a blocking layer formed on inner walls of the respective sub-channel holes (not shown) to block charge flow out; a charge trapping layer formed on a surface of the blocking layer to store charge during operation of the semiconductor device; and a tunneling layer formed on a surface of the charge trapping layer.

In some implementations, the sub-functional layer may include an ONO structure. However, in some other implementations, the sub-functional layer may also have a structure different from the ONO configuration. The sub-channel layer may be formed on a surface of the tunneling layer and can be configured to transport a desired charge (electrons or holes).

In an example, the sub-channel layer may be made of a semiconductor material such as polycrystalline silicon or monocrystalline silicon, and may have conductive impurities. For example, the first sub-channel layer 3011, the second sub-channel layer 3021 and the third sub-channel layer 3031 may each include N-type doped or P-type doped polysilicon layers. In addition, each of the sub-channel layers may have a cylindrical or pillar shape extending along the z direction.

The second semiconductor layer 420 may also be made of a semiconductor material such as polysilicon or monocrystalline silicon, and may have conductive impurities. In an example, doping types of the sub-channel layer and the second semiconductor layer 420 may be the same. In addition, a doping concentration of conductive impurities of the second semiconductor layer 420 may be greater than a doping concentration of conductive impurities of the sub-channel layer. In other words, the drain or source having a relatively high conductive impurity doping concentration can improve the mobility of electrons or holes in the channel, thereby improving the response speed of the semiconductor device.

In addition, in some implementations of the present disclosure, the second semiconductor layer 420 may be located on a side of the sub-stacked structure away from the peripheral circuit along the z direction. For example, the peripheral circuit structure 600 may be disposed on at least one of the first side 01 and the second side 02 of the stacked structure 200. Taking the peripheral circuit structure 600 located on the first side 01 as an example, the first sub-semiconductor layer 421 may be located on a side of the first sub-stacked structure 201 away from the peripheral circuit structure 600; the second sub-semiconductor layer 422 may be located on a side of the second sub-stacked structure 202 away from the peripheral circuit structure 600; and the third sub-semiconductor layer 423 may be located on a side of the third sub-stacked structure 203 away from the peripheral circuit structure 600.

In addition, in some implementations of the present disclosure, the select gate layer may be located on a side of the plurality of gate layers away from the second semiconductor layer 420 along the z direction. For example, the first select gate layer 211 may be located on a side of the plurality of first gate layers 212 away from the first sub-semiconductor layer 421 along the z direction; the second select gate layer 221 may be located on a side of the plurality of second gate layers 222 away from the second sub-semiconductor layer 422 along the z direction; and the third select gate layer 231 may be located on one side of the plurality of third gate layers 232 away from the third gate layer 232 along the z direction.

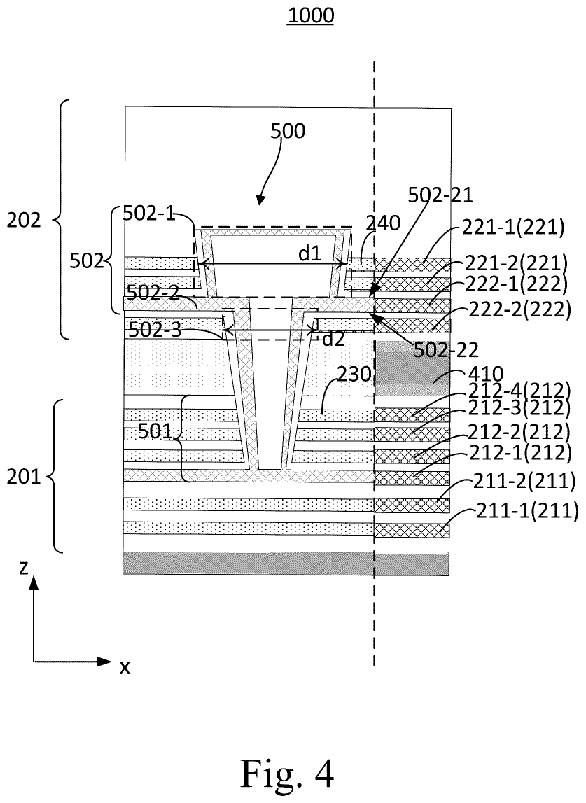

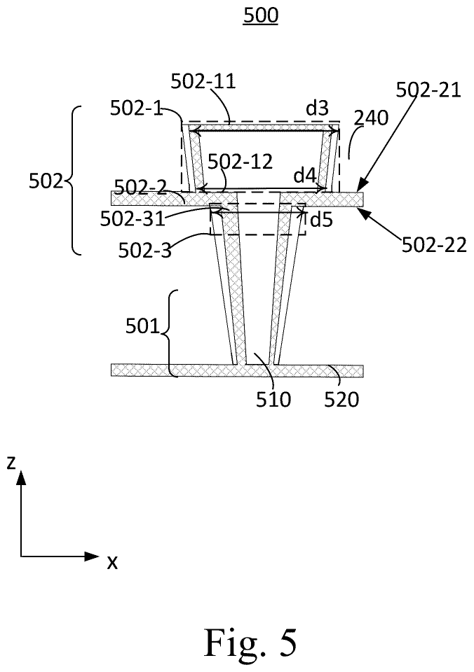

FIG. 4 is a schematic partial cross-sectional view of a semiconductor device 1000 according to an implementation of the present disclosure. FIG. 5 is a schematic cross-sectional view of a contact structure 500 according to an implementation of the present disclosure.

With reference to FIG. 1, FIG. 2, FIG. 4 and FIG. 5, in some implementations of the present disclosure, the contact structure 500 may include a first section 501 located in the first sub-stacked structure 201 and a second section 502 located in one of the remaining sub-stacked structures. For example, the contact structure 500 shown in FIG. 1 may include a first section 501 located in the first sub-stacked structure 201 and a second section 502 located in the second sub-stacked structure 202; and the contact structure 500 shown in FIG. 2 may include a first section 501 located in the first sub-stacked structure 201, a second section 502 located in the second sub-stacked structure 202, and another second section 502′ located in the third sub-stacked structure 203.

As shown in FIG. 1 and FIG. 4, taking the second section 502 of the second sub-stacked structure 202 as an example, the second section 502 may include a first portion 502-1, a second portion 502-2 and a third portion 502-3, and the second portion 502-2 extends along a direction intersecting the z direction (e.g., the x direction) and is connected to the second gate layers 222 of the second sub-stacked structure 202. In addition, the second portion 502-2 may include two sides disposed opposite to each other along the z direction, for example, a first side 502-21 and a second side 502-22, and the first portion 502-1 and the third portion 502-3 are respectively located on the first side 502-21 and the second side 502-22 and connected to the second portion 502-2.

Specifically, the first sub-stacked structure 201 may include a plurality of first select gate layers 211, such as a first sub-select gate layer 211-1, a second sub-select gate layer 211-2, and the like. In addition, the first sub-stacked structure 201 may further include a plurality of first gate layers 212, such as a first sub-gate layer 212-1, a second sub-gate layer 212-2, a third sub-gate layer 212-3 and a fourth sub-gate layer 212-4. In an example, the first section 501 of the contact structure 500 located in the first sub-stacked structure 201 is connected to the first sub-gate layer 212-1.

In addition, the contact structure 500 further includes a second section 502 located in the second sub-stacked structure 202 and a portion located in the semiconductor layer 410. It should be noted that the present disclosure is only for ease of description, and throughout the disclosure, the contact structure 500 is divided into a plurality of portions and each portion is named. It should be understood by those skilled in the art that the contact structure 500 is actually an integral structure, and in the actual integral structure, the plurality of portions has no obvious boundaries.

The second sub-stacked structure 202 may include a plurality of second select gate layers 221, such as a third select gate layer 221-1, a fourth select gate layer 221-2, and so on. In addition, the second sub-stacked structure 202 may further include a plurality of second gate layers 222, such as a fifth sub-gate layer 222-1, a sixth sub-gate layer 222-2, and the like. In an example, the second section 502 of the contact structure 500 located in the second sub-stacked structure 202 is connected to the fifth sub-gate layer 222-1.

In addition, the second portion 502-2 of the contact structure 500 is disposed in the same layer as the gate layer of one of the remaining sub-stacked structures. For example, the contact structure 500 shown in FIG. 4 is located in the second section 502 of the second sub-stacked structure 202, and the second portion 502-2 is disposed in the same layer as the fifth sub-gate layer 222-1 of the second sub-stacked structure 202.

In an example, along a direction intersecting the z direction (e.g., x direction), a dimension d1 of the first portion 502-1 of the contact structure 500 is greater than a dimension d2 of the third portion 502-3 of the contact structure 500, where the dimension dl of the first portion 502-1 of the contact structure 500 may be understood as a cross-sectional dimension of the first portion at any stack height of the remaining sub-stacked structures; and the dimension d2 of the third portion 502-3 of the contact structure 500 may be understood as a cross-sectional dimension of the third portion at any stack height of the remaining sub-stacked structures.

As shown in FIG. 5, in some implementations of the present disclosure, the first portion 502-1 of the contact structure 500 may include a first end 502-11 and a second end 502-12 opposite to each other along the z direction, and the second end 502-12 is connected to the second portion 502-2 of the contact structure 500. Along a direction intersecting the z direction (e.g., x direction), the dimension d3 of the first end 502-11 is greater than the dimension d4 of the second end 502-12. In an example, the shape of the first portion 502-1 of the contact structure 500 may include a frustum, such as a truncated cone, a pyramid, or the like.

Further, the third portion 502-3 of the contact structure 500 may include a third end 502-31 connected with the second portion 502-2. Along a direction intersecting the z direction (e.g., x direction), the dimension d4 of the second end 502-12 of the first portion 502-1 of the contact structure 500 is greater than the dimension d5 of the third end 502-31 of the third portion 502-3 of the contact structure 500. In an example, the shape of the third portion 502-3 of the contact structure 500 may include a frustum, such as a truncated cone, a pyramid, or the like.

With reference to FIG. 1 and FIG. 4, in some implementations of the present disclosure, the peripheral circuit structure 600 is located on the first side 01 of the stacked structure 200, and the first portion 502-1 of the contact structure 500 is closer to the peripheral circuit structure 600 than the third portion 502-3 of the contact structure 500.

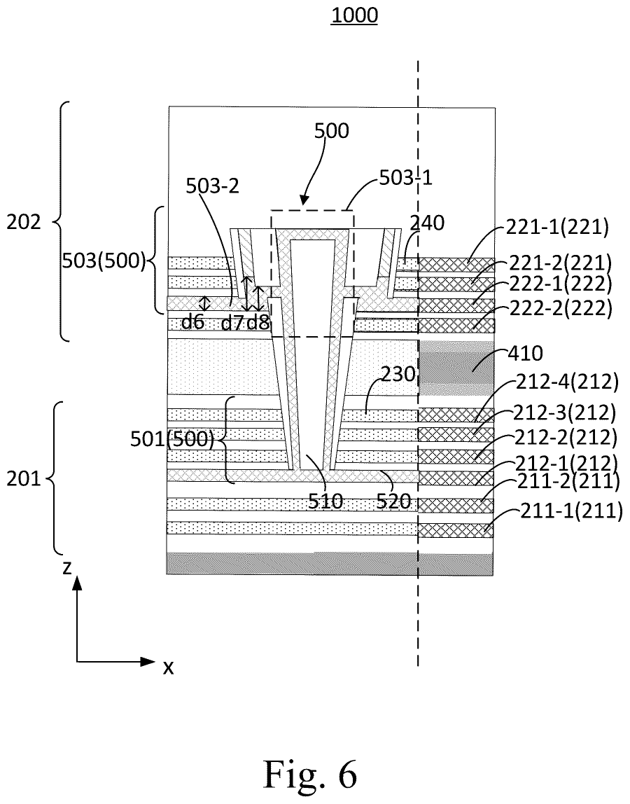

FIG. 6 is a schematic partial cross-sectional view of a semiconductor device 1000 according to an implementation of the present disclosure.

As shown in FIG. 6, in some other implementations of the present disclosure, the contact structure 500 may include a first section 501 located in the first sub-stacked structure 201 and a third section 503 located in one of the remaining sub-stacked structures, for example, FIG. 6 shows the third section 503 located in the second sub-stacked structure 202.

The third section 503 of the contact structure 500 may include a fourth portion 503-1 and a fifth portion 503-2 connected to each other. The fourth portion 503-1 passes through the remaining sub-stacked structures along a direction intersecting the z direction and connects the first section 501 of the contact structure 500. The fifth portion 503-2 is connected to gate layers of one of the remaining sub-stacked structures.

For example, the fourth portion 503-1 shown in FIG. 6 passes through the second sub-stacked structure 202 along a direction intersecting the z direction and connects the first section 501 of the contact structure 500, where the direction intersecting the z direction may be an acute direction intersecting the z direction. In addition, the fifth portion 503-2 is connected to the fifth sub-gate layer 222-1 of the second sub-stacked structure 202.

In an example, the fifth portion 503-2 of the contact structure 500 may have a different thickness along a direction intersecting the z direction (e.g., x direction), where the thickness is a dimension of the fifth portion 503-2 along the z direction. For example, the thickness dimensions of the fifth portion 503-2 along the x direction may include a first dimension d6, a second dimension d7, a third dimension d8, and the like, where the first dimension d6, the second dimension d7 and the third dimension d8 are not equal.

In addition, referring to FIG. 5 and FIG. 6, in some implementations of the present disclosure, the contact structure 500 may include a dielectric filling layer 510 and a conductive structure layer 520 surrounding the dielectric filling layer 510, where the dielectric filling layer 510 may be, for example, a dielectric material such as silicon oxide, silicon nitride and silicon oxynitride, the conductive structure layer 520 may include a conductive material, where the conductive material may include one or more of a conductive metal material and a doped semiconductor material, where the conductive metal material may be, for example, tungsten (W), cobalt (Co), copper (Cu), aluminum (Al), or the like, and the doped semiconductor material may be, for example, doped crystalline silicon or silicide, which is not limited in the present disclosure.

In other words, the contact structure 500 is an integral structure, and may include a dielectric filling layer 510 and a conductive structure layer 520 surrounding the dielectric filling layer 510. The contact structure includes a dielectric filling layer surrounded by the conductive structure layer, so that the use of conductive materials in the contact structure can be reduced, and the effects of reducing the manufacturing cost of the semiconductor device and reducing the stress deformation of the stacked structure are achieved. It should be noted that the present disclosure divides the contact structure 500 into a plurality of portions, such as a first section, a second section, or a first section, a third section, etc., for ease of description only, where each portion may include a portion of the dielectric filling layer and a portion of the conductive structure layer.

Thus, according to at least one implementation of the present disclosure, a stacked structure of a semiconductor device may include a plurality of sub-stacked structures stacked along a first direction, where a contact structure extends along the first direction and is connected to gate layers of the plurality of sub-stacked structures. In addition, the semiconductor device may control different sub-stacked structures to work independently by select gate layers connected to a peripheral circuit. Therefore, this allows the plurality of sub-stacked structures, on the basis of realizing independent operation, to be connected with the peripheral circuit through the same contact structure, thus, the number of contact structures in the semiconductor device is reduced, and the storage density of the semiconductor device is improved, meanwhile the manufacturing process of the contact structure is simplified, and the manufacturing cost of the semiconductor device is reduced.

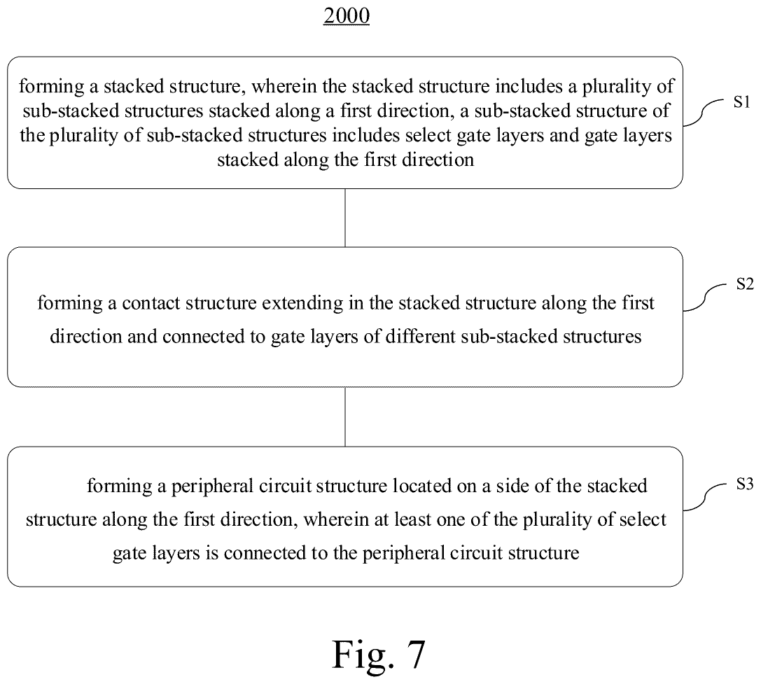

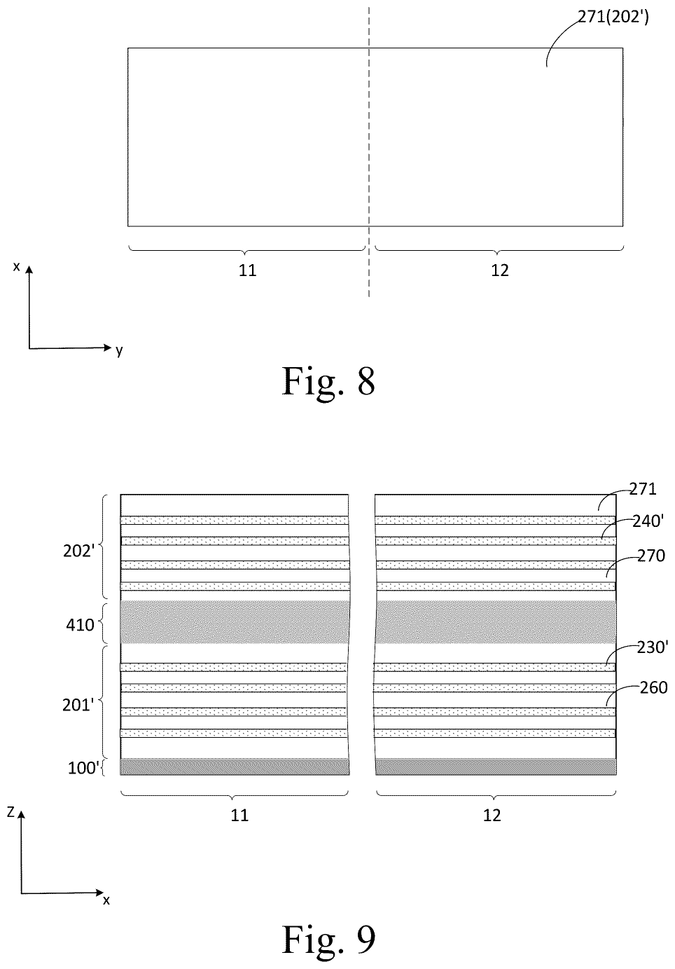

FIG. 7 is a flowchart of a method of manufacturing 2000 a semiconductor device according to an implementation of the present disclosure. FIGS. 8-25 are schematic views of a method of manufacturing 2000 a semiconductor device according to an implementation of the present disclosure.

As shown in FIG. 7, the method of manufacturing 2000 a semiconductor device may include operations S1-S3.

At operation S1, the method may include forming a stacked structure, where the stacked structure includes a plurality of sub-stacked structures stacked along a first direction, a sub-stacked structure of the plurality of sub-stacked structures includes select gate layers and gate layers stacked along the first direction.

At operation S2, the method may include forming a contact structure extending in the stacked structure along the first direction and connected to gate layers of the plurality of sub-stacked structures.

At operation S3, the method may include forming a peripheral circuit structure, where at least one of the plurality of select gate layers is connected to the peripheral circuit structure.

The specific process of each operation of the manufacturing method 2000 in the implementation of the present disclosure will be described in detail below with reference to FIG. 7 to FIG. 25.

### Operation S1

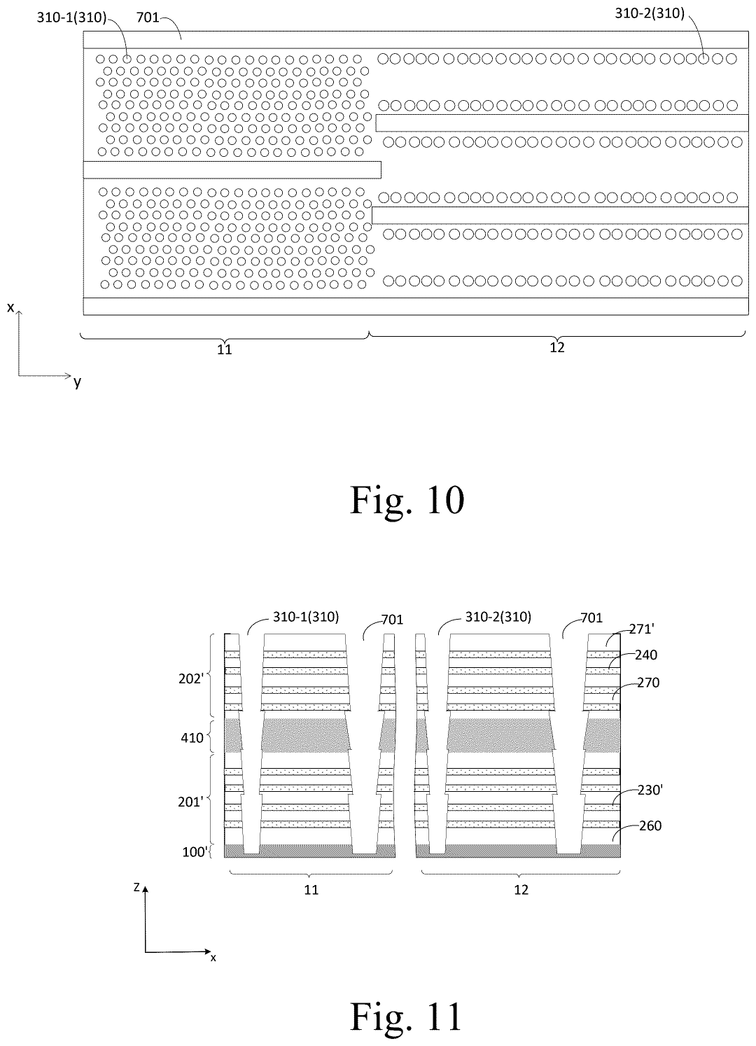

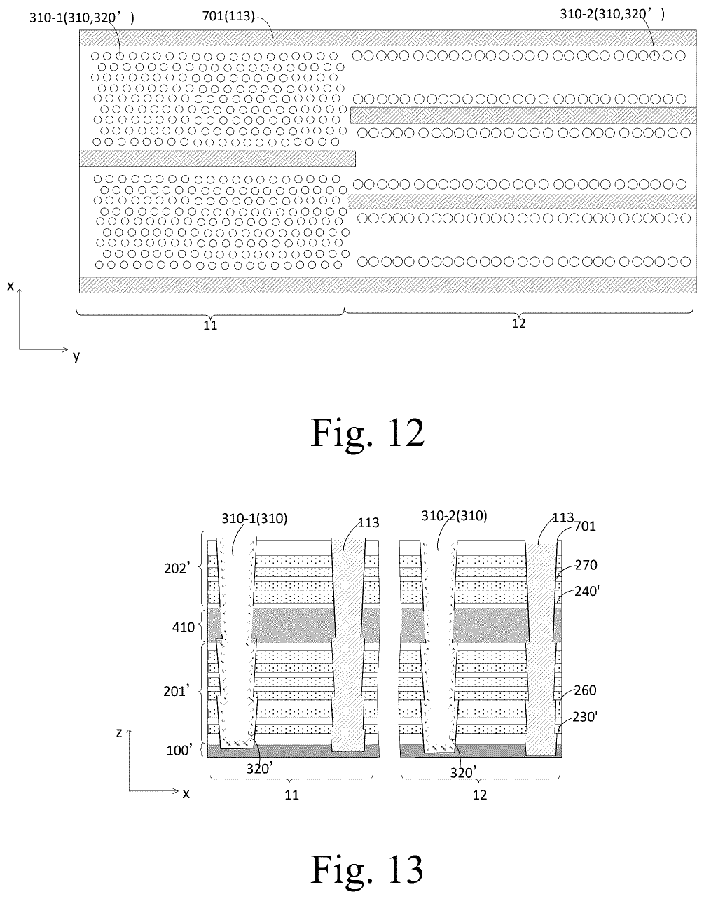

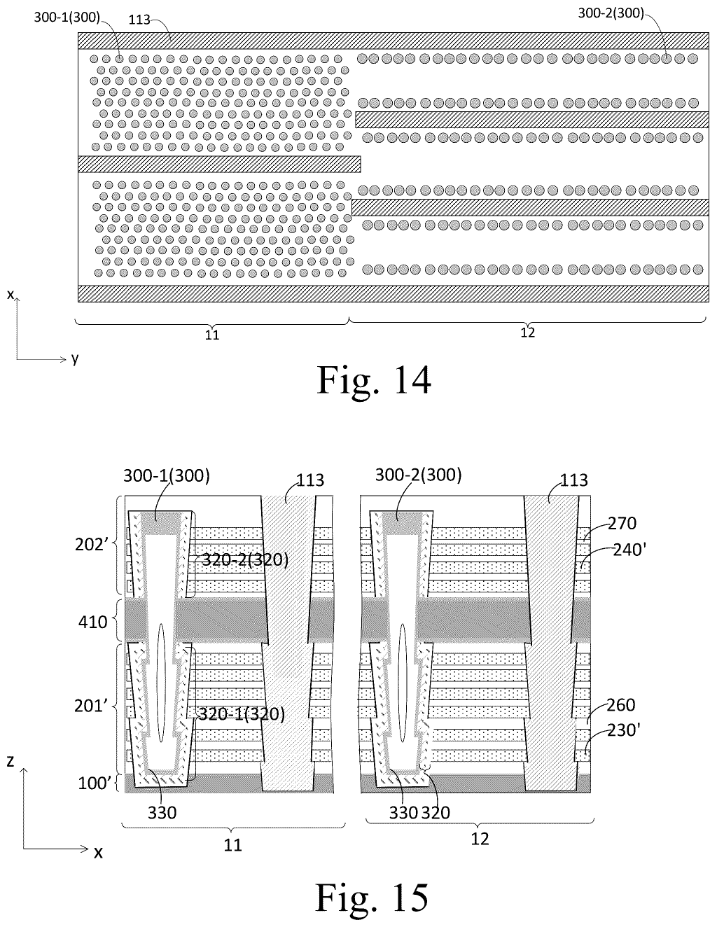

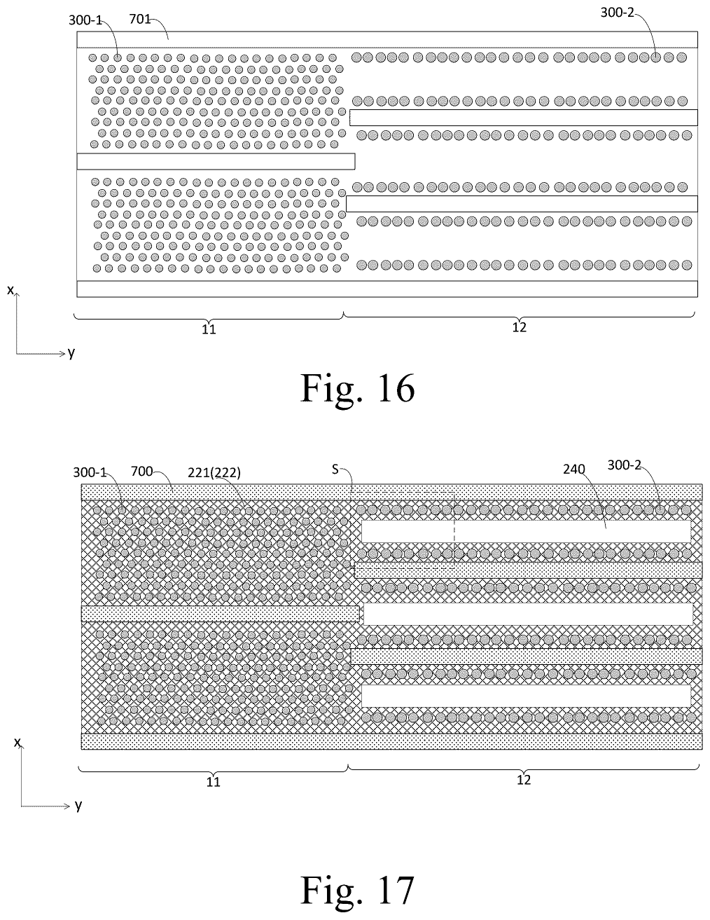

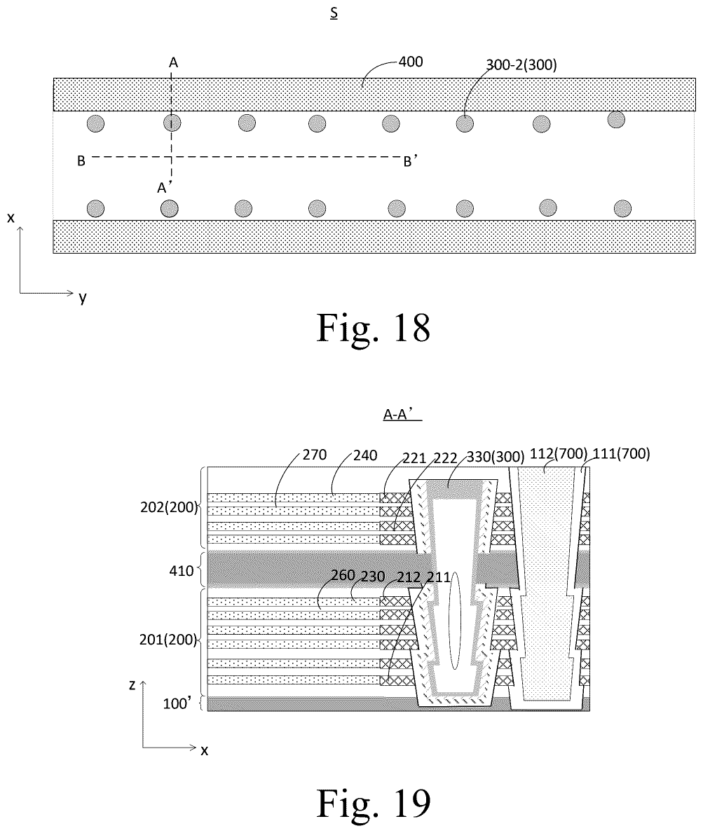

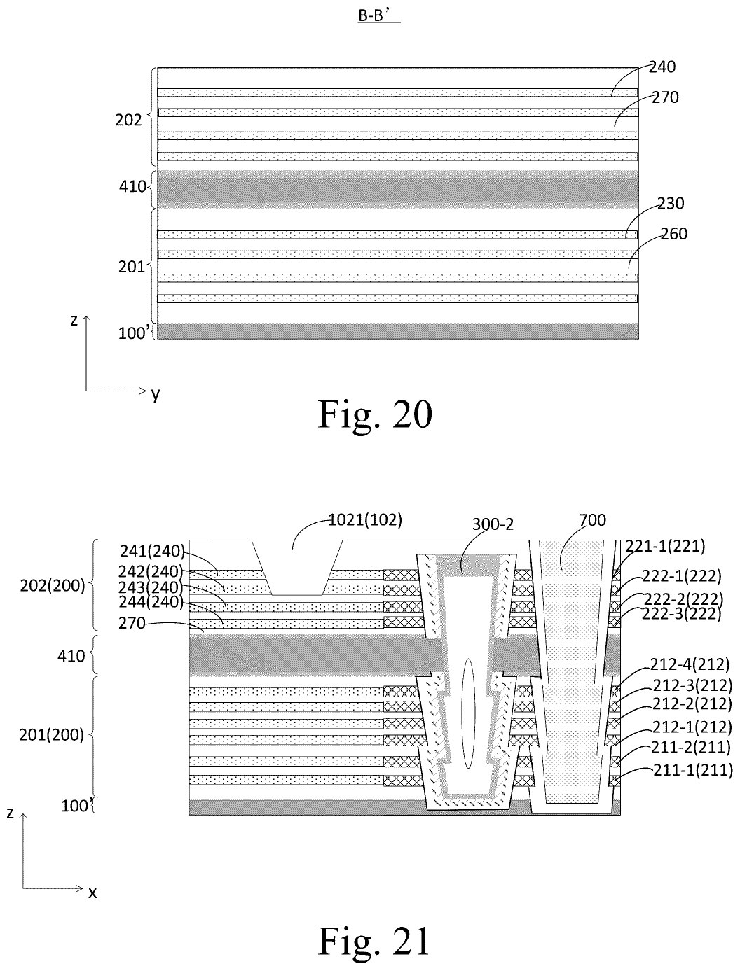

FIG. 8 is a schematic top view of a structure formed after forming a second sub-stacked structure 202′ according to a manufacturing method of an implementation of the present disclosure. FIG. 9 is a schematic cross-sectional view of a structure formed after forming a second sub-stacked structure 202′ according to a manufacturing method of an implementation of the present disclosure. FIG. 10 is a schematic top view of a structure formed after forming a channel hole 310 according to a manufacturing method of an implementation of the present disclosure. FIG. 11 is a schematic cross-sectional view of a structure formed after forming a channel hole 310 according to a manufacturing method of an implementation of the present disclosure. FIG. 12 is a schematic top view of a structure formed after forming an initial functional layer 320′ according to a manufacturing method of an implementation of the present disclosure. FIG. 13 is a schematic cross-sectional view of a structure formed after forming an initial functional layer 320′ according to a manufacturing method of an implementation of the present disclosure. FIG. 14 is a schematic top view of a structure formed after forming a channel structure 300 according to a manufacturing method of an implementation of the present disclosure. FIG. 15 is a schematic cross-sectional view of a structure formed after forming a channel structure 300 according to a manufacturing method of an implementation of the present disclosure. FIG. 16 is a schematic top view of a structure formed after exposing a gate line slit 701 according to a manufacturing method of an implementation of the present disclosure. FIG. 17 is a schematic perspective view of a structure formed after forming a gate line isolation structure 700 according to a manufacturing method of an implementation of the present disclosure. FIG. 18 is an enlarged schematic view of the structure shown in FIG. 17 at S. FIG. 19 is a schematic cross-sectional view of the structure shown in FIG. 18 taken along line A-A′. FIG. 20 is a schematic cross-sectional view of the structure shown in FIG. 18 taken along line B-B′.

As shown in FIGS. 7-20, operation S1 for forming a stacked structure, where the stacked structure includes a plurality of sub-stacked structures stacked along a first direction and a sub-stacked structure of the plurality of sub-stacked structures the includes select gate layers and gate layers stacked along the first direction, may, for example, include: alternately stacking first dielectric layers 260 and first gate sacrificial layers 230′ to form a first sub-stacked structure 201′; forming a semiconductor layer 410 on a side of the first sub-stacked structure 201′ along a first direction (z direction); alternately stacking second dielectric layers 270 and second gate sacrificial layers 240′ on a side of the semiconductor layer 410 along the z direction to form a second sub-stacked structure 202′; and replacing portions of the first gate sacrificial layers 230′ and portions of the second gate sacrificial layers 240′ with gate layers.

Specifically, in the following implementations, a process of forming a stacked structure including two sub-stacked structures is described as an example, but the number of stacked structures and specific structures of the stacked structures are not limited in this application. In other words, the content, the manufacturing method, the structure and the beneficial effects involved in the manufacturing method of the semiconductor device of the two sub-stacked structures (for example, the first sub-stacked structure and the second sub-stacked structure) described in the present disclosure may be completely or partially applicable to the manufacturing method of the semiconductor device including a plurality of sub-stacked structures, and thus related or similar contents thereof are not described again.

As shown in FIGS. 8-9, in some implementations of the present disclosure, before forming the first sub-stacked structure 201′, the method of manufacturing 2000 a semiconductor device further includes providing a substrate 100′.

In an example, the substrate 100′ may be made of any suitable semiconductor material such as monocrystalline silicon (Si), monocrystalline germanium (Ge), silicon germanium (GeSi), silicon carbide (SiC), silicon-on-insulator (SOI), germanium-on-insulator (GOI), or such as III-V compounds gallium arsenide. In addition, the substrate 100′ may include a monocrystalline silicon.

In an implementation of the present disclosure, the substrate 100′ may include, for example, a composite substrate for supporting a device structure thereon. The substrate 100′ may be formed by sequentially disposing a plurality of layers made of different materials by a thin film deposition process such as chemical vapor deposition (CVD), physical vapor deposition (PVD), atomic layer deposition (ALD), or any combination thereof.

The substrate 100′ may include a substrate sacrificial layer for subsequently forming a semiconductor connection layer connecting the channel structure. The substrate sacrificial layer may include a single layer, multiple layers, or a suitable composite layer. For example, the substrate sacrificial layer may include any one or more of a silicon oxide layer, a silicon nitride layer, and a silicon oxynitride layer. In an example, the substrate sacrificial layer may be a high-k dielectric layer, and in another example, the substrate sacrificial layer may include a dielectric layer, a sacrificial layer and a dielectric layer that are sequentially disposed, where the dielectric layer may include a silicon nitride layer, and the sacrificial layer may include a silicon oxide layer. In an example, the substrate sacrificial layer may include any one or more of a dielectric material, a semiconductor material and a conductive material. For example, the sacrificial layer may include monocrystalline silicon or polycrystalline silicon, and specifically, in an implementation of the present disclosure, an exemplary material for forming the sacrificial layer may be polycrystalline silicon.

A partial region of the substrate 100′ may also form a well region formed by doping N-type or P-type dopants via an ion implantation or diffusion process. The dopant may include one or more of phosphorus (P), arsenic (As) and antimony (Sb). In some implementations of the present disclosure, the well region may be prepared with the same dopant or different dopants, and doping concentration of the well region may be the same or different, which is not limited in the present disclosure.

As shown in FIG. 8 and FIG. 9, in some implementations of the present disclosure, forming the first sub-stacked structure 201 and the second sub-stacked structure 202 located on a side of the first sub-stacked structure 201 along the z direction may include: alternately stacking the first dielectric layers 260 and the first gate sacrificial layers 230′ to form the first sub-stacked structure 201′; forming the semiconductor layer 410 on a side of the first sub-stacked structure 201′ along the z direction; alternately stacking the second dielectric layers 270 and the second gate sacrificial layers 240′ on a side of the semiconductor layer 410 along the z direction to form the second sub-stacked structure 202′; and replacing portions of the first gate sacrificial layers 230′ and portions of the second gate sacrificial layers 240′ with the first gate layers 212 and the second gate layers 222 respectively (referring to FIG. 1).

Specifically, after the substrate 100′ is formed, the first sub-stacked structure 201′ may be formed on a side of the substrate 100′ through one or more thin film deposition processes, and the thin film deposition processes may include, but is not limited to, chemical vapor deposition (CVD), physical vapor deposition (PVD), atomic layer deposition (ALD) or any combination thereof, which is not limited in the present disclosure.

The first sub-stacked structure 201′ may include a plurality of pairs of first dielectric layers 260 and first gate sacrificial layers 230′ alternately stacked with each other. For example, the first sub-stacked structure 201′ may include a plurality of pairs of dielectric layers, such as 64 pairs, 128 pairs, or more than 128 pairs of the first dielectric layers 260 and the first gate sacrificial layers 230′.

In some implementations, the first dielectric layer 260 and the first gate sacrificial layer 230′ may include a first dielectric material and a second dielectric material different from the first dielectric material, respectively. Exemplary materials for forming the first dielectric layer 260 and the first gate sacrificial layer 230′ may include silicon oxide and silicon nitride, respectively. Silicon oxide layers may serve as isolation stack layers, while silicon nitride layers may serve as sacrificial stack layers. A portion of the sacrificial stack layers may then be etched away and replaced with conductor layers including conductive materials to form first gate layers of the semiconductor device.

After the first sub-stacked structure 201′ is formed, a stacked structure may be formed by sequentially stacking a plurality of sub-stacked structures along the z direction by using a dual-stack technology or a multi-stack technology, where each sub-stacked structure may include a plurality of stacked dielectric layer pairs. The number of layers of each sub-stacked structure may be the same or different. Since the content and structure involved in the manufacturing process of a single stacked structure described above may be completely or partially applicable to the stacked structure formed by the plurality of sub-stacked structures described herein, details related thereto or similar thereto are not described again. However, those skilled in the art may understand that a subsequent manufacturing process may be performed on the basis of a double-stacked structure or a multi-stacked structure, where the number of sub-stacked structures in the multi-stacked structures is greater than or equal to 2.

Referring to FIG. 9, the second sub-stacked structure 202′ may be formed on a side of the first sub-stacked structure 201 through one or more thin film deposition processes which may include, but are not limited to, chemical vapor deposition (CVD), physical vapor deposition (PVD), atomic layer deposition (ALD), or any combination thereof.

The second sub-stacked structure 202′ may include a plurality of pairs of second dielectric layers 270 and second gate sacrificial layers 240′ alternately stacked with each other. For example, the second sub-stacked structure 202′ may include a plurality of pairs of dielectric layers, such as 64 pairs, 128 pairs, or more than 128 pairs of the second dielectric layers 270 and the second gate sacrificial layers 240′.

It should be noted that a size of a dielectric layer 271 farthest from the substrate 100′ in the plurality of second dielectric layers 270 along the z direction may be greater than or equal to a size of any of the remaining second dielectric layers 270 along the z direction.

In addition, in some implementations of the present disclosure, before forming the second sub-stacked structure 202′, a semiconductor layer 410 may also be formed on a side of the first sub-stacked structure 201′ far away from the substrate 100′.

Specifically, the semiconductor layer 410 may be formed by one or more thin film deposition processes which may include, but are not limited to, chemical vapor deposition (CVD), physical vapor deposition (PVD), atomic layer deposition (ALD), or any combination thereof. The materials of the semiconductor layer 410 may include semiconductor materials such as polycrystalline silicon or monocrystalline silicon. In addition, the semiconductor layer 410 may further include N-type doped or P-type doped conductive impurities. The semiconductor layer 410 may extend along a direction intersecting the z direction (e.g., x direction, y direction).

After the semiconductor layer 410 is formed, the second sub-stacked structure 202′ may be formed by the above method. In other words, the semiconductor layer 410 is located between the first sub-stacked structure 201′ and the second sub-stacked structure 202′ along the z direction.

The stacked structure having the first sub-stacked structure 201′ and the second sub-stacked structure 202′ may include a first region 11 and a second region 12 arranged adjacent to each other along y direction intersecting the z direction, where the first region 11 may be configured to form a channel structure having a storage function, the second region 12 may be configured to form a contact structure, where the contact structure may form a connection with subsequently formed gate layers.

As shown in FIG. 10 to FIG. 15, in some implementations of the present disclosure, the method of manufacturing 2000 a semiconductor device further includes forming a channel structure 300, where forming the channel structure 300 may include, for example: forming a channel hole 310 extending in the first sub-stacked structure 201′ and the second sub-stacked structure 202′ along the z direction, where the channel hole 310 exposes a portion of the semiconductor layer 410; forming initial functional layers 320′ in the channel hole 310; removing a portion of the initial functional layers 320′ located on the exposed semiconductor layer 410 to form a first functional layer 320-1 and a second functional layer 320-2, where the first functional layer 320-1 extends in the first sub-stacked structure 201′ along the z direction, and the second functional layer 320-2 extends in the second sub-stacked structure 202′ along the z direction; and forming a channel layer 330 on surfaces of the first functional layer 320-1, the semiconductor layer 410, and the second functional layer 320-2.

The channel structure 300 may include a semiconductor layer and a composite dielectric layer filled in the channel hole 310, for example, the channel structure 300 may include a functional layer 320 and a channel layer 330 surrounded by the functional layer 320. In addition, a plurality of channel structures 300 may include a plurality of first channel structures 300-1 located in the first region 11 and having storage function, and a plurality of second channel structures 300-2 located in the second region 12.

Specifically, as shown in FIGS. 10-11, a plurality of channel holes 310 may be formed by, for example, a dry etching process or a combination of a dry etching process and a wet etching process; and other manufacturing processes may also be performed, such as a patterning process including photolithography, cleaning and chemical mechanical polishing, etc., where the plurality of channel holes 310 may include a plurality of first channel holes 310-1 located in the first region 11 and a plurality of second channel holes 310-2 located in the second region 12. The channel holes 310 may expose a portion of the semiconductor layer 410.

In an example, the channel hole 310 passes through the second sub-stacked structure 202′, the semiconductor layer 410, and the first sub-stacked structure 201′ along the z direction, and extends into the substrate 100′.

In an example, the plurality of channel holes 310 may have the same depth along the z direction, so as to reduce the difficulty of manufacturing the semiconductor device and reduce the cost of manufacturing the semiconductor device. In an example, the aperture size of the second channel hole 310-2 may be larger than the aperture size of the first channel hole 310-1.

As shown in FIGS. 10-13, after forming the plurality of channel holes 310, initial functional layers 320′ may be formed on inner walls of the channel holes 310 through a thin film deposition process such as chemical vapor deposition (CVD), physical vapor deposition (PVD), atomic layer deposition (ALD), or any combination thereof.

The initial functional layer 320′ may include a blocking layer formed on inner walls of the channel holes 310 and on the exposed semiconductor layer 410 to block charge flow out; a charge trapping layer formed on a surface of the blocking layer to store charge during operation of the semiconductor device; and a tunneling layer formed on a surface of the charge trapping layer.

In some implementations of the present disclosure, the initial functional layer 320′ may include an ONO structure. However, in some other implementations, the initial functional layer 320′ may have a structure different from the ONO configuration.

In addition, those skilled in the art should understand that, without departing from the teachings of the present disclosure, an initial functional layer may be formed on sidewalls and the bottom surface of a channel hole, or the initial functional layer may be formed on the sidewalls of the channel hole, which is not limited in the present disclosure.

As shown in FIGS. 12-15, by, for example, a dry etching process or a combination of a dry etching process and a wet etching process; or by performing other manufacturing processes such as a patterning process including photolithography, cleaning and chemical mechanical polishing, a portion of the initial functional layer 320′ located on the exposed semiconductor layer 410 is removed, so as to form a first functional layer 320-1 and a second functional layer 320-2, where the first functional layer 320-1 extends in the first sub-stacked structure 201′ along the z direction, and the second functional layer 320-2 extends in the second sub-stacked structure 202′ along the z direction.

In an example, after removing the portion of the initial functional layer 320′ located on the exposed semiconductor layer 410 and re-exposing a portion of the semiconductor layer 410, a new semiconductor material layer may be formed on the surface of the re-exposed semiconductor layer 410 through a thin film deposition process such as chemical vapor deposition (CVD), physical vapor deposition (PVD), atomic layer deposition (ALD), or any combination thereof, so as to reduce damage to the semiconductor layer 410 during the process of “removing the portion of the initial functional layer 320′ located on the exposed semiconductor layer 410”.

After forming the first functional layer 320-1 and the second functional layer 320-2, the channel layer 330 may be formed on surfaces of the first functional layer 320-1, the semiconductor layer 410, and the second functional layer 320-2 through a thin film deposition process such as chemical vapor deposition (CVD), physical vapor deposition (PVD), atomic layer deposition (ALD), or any combination thereof. In other words, the surface of the channel layer 330 is in direct contact with the surface of the semiconductor layer 410, thereby connecting the channel layer 330 and the semiconductor layer 410.

In an example, the channel layer 330 may be configured to transport a desired charge (electrons or holes). The channel layer 330 may be made of semiconductor materials such as polysilicon or monocrystalline silicon, and may have conductive impurities. For example, the channel layer 330 may include an N-type doped or P-type doped polysilicon layer. Similar to the channel hole 310, the channel layer 330 may also have a cylindrical or pillar shape extending along the z direction. In an example, the channel layer 330 may extend into the substrate 100′.

In addition, as shown in FIG. 15, the channel structure 300 further includes channel plugs formed at an end (which may be understood as a top of the channel structure 300) of the channel holes 310 far away from the substrate 100′. Specifically, after the channel layer 330 is formed, the channel hole 310 may be filled with channel filling dielectric layer (as shown in FIG. 13). The channel filling dielectric layer may include oxide dielectric layer such as silicon oxide or the like. In addition, during the filling process, a plurality of insulating gaps may be formed in the channel filling dielectric layers by controlling the channel filling process to relieve the structural stress. Channel plugs are then formed in portions of the channel filling dielectric layer located on tops of the channel holes 310. The channel plug may be made of the same material as the channel layer 330, such as N-type doped or P-type doped polysilicon. The channel plug is connected to the channel layer 330.

In addition, as shown in FIGS. 10-15, in an example, based on the second channel structure 300-2 having no storage function, only an insulating dielectric material layer such as a silicon oxide layer may be filled in the second channel hole 310-2 through a thin film deposition process such as chemical vapor deposition (CVD), physical vapor deposition (PVD), atomic layer deposition (ALD), or any combination thereof. Similarly, a plurality of insulating gaps may also be formed in the insulating dielectric material layer by controlling the channel filling process to relieve the structural stress of the second channel structure 300-2.

In addition, referring to FIG. 10 to FIG. 20, in some implementations of the present disclosure, the method 2000 further includes forming a gate line isolation structure 700.

Gate line slits 701 generated during the forming of the gate line isolation structure 700 may serve as paths for providing an etchant, so that a portion of the first gate sacrificial layer 230′ and a portion of the second gate sacrificial layer 240′ may be removed by using a process such as wet etching, and the first gate layer 212 and the second gate layer 222 (referring to FIG. 1) are formed in a void (not shown) formed after the portion of the first gate sacrificial layer 230′ and the portion of the second gate sacrificial layer 240′ are removed.

Specifically, as shown in FIG. 10 to FIG. 11, the gate line slits 701 may be formed by, for example, a dry etching process or a combination of a dry etching process and a wet etching process; and other manufacturing processes may also be performed, such as a patterning process including photolithography, cleaning, and chemical mechanical polishing. At least one of the plurality of gate line slits 701 may extend from the first region 11 into the second region 12 in y direction; alternatively, at least one of the plurality of gate line slits 701 may extend in the first region 11 along the y direction; alternatively, at least one of the plurality of gate line slits 701 may extend in the second region 12 along the y direction. In addition, the gate line slit 701 may pass through the second sub-stacked structure 202′, the semiconductor layer 410, and the first sub-stacked structure 201′ along the z direction, and extend into the substrate 100′.

In an example, as shown in FIG. 10 to FIG. 15, the gate line slit sacrificial layer 113 may be filled in the gate line slit 701 during the process of forming the channel structure 300. The gate line slit sacrificial layer 113 may include a carbon-containing material layer, a polysilicon material layer, or the like. The gate line slit sacrificial layer 113 may be formed of materials having a high deposition rate to facilitate rapid filling of the gate line slit 701, and the gate line slit sacrificial layer 113 should be any material having a high dry etching selectivity with respect to the first dielectric layer 260, the second dielectric layer 270, the first gate sacrificial layer 230′ and the second gate sacrificial layer 240′, to facilitate removal in subsequent operations.

As shown in FIGS. 14-16, by, for example, a dry etching process or a combination of a dry etching process and a wet etching process; or by performing other manufacturing processes such as a patterning process including photolithography, cleaning and chemical mechanical polishing, the gate line slit sacrificial layer is removed to expose the gate line slit 701, and a portion of the first gate sacrificial layers 230′ and a portion of the second gate sacrificial layer 240′ may be removed by virtue of the gate line slit 701.

Referring to FIGS. 15 and 16, at least one of the plurality of gate line slits 701 may extend from the first region 11 into the second region 12 along the y direction; alternatively, at least one of the plurality of gate line slits 701 may extend in the first region 11 along the y direction; alternatively, at least one of the plurality of gate line slits 701 may extend in the second region 12 along the y direction. Therefore, portions of the first gate sacrificial layers 230′ and the second gate sacrificial layers 240′ located in the first region 11 may be removed by virtue of portions of the plurality of gate line slits 701 located in the first region 11, and portions of the first gate sacrificial layers 230′ and the second gate sacrificial layer 240′ located in the second region 12 adjacent to the gate line slits 701 may be removed by virtue of portions of the plurality of gate line slits 701 located in the second region 12.

Specifically, in the process of removing a portion of the first gate sacrificial layers 230′ and a portion of the second gate sacrificial layers 240′ by using a process such as wet etching, an etchant and a chemical precursor may contact a portion of the first gate sacrificial layers 230′ and a portion of the second gate sacrificial layers 240′ via the gate line slits 701, and then the portion of the first gate sacrificial layers 230′ and the portion of the second gate sacrificial layers 240′ are removed to form sacrificial voids (not shown).

In addition, in at least one implementation of the present disclosure, the layout of the gate line slits 701 in the x-y plane may be selected according to different settings of a finally formed semiconductor device architecture, so as to reduce the size of the gate line isolation structure formed based on the gate line slits 701 and increase the storage density of the finally formed semiconductor device while optimizing the process window for removing the gate sacrificial layers.

As shown in FIGS. 16-20, the first gate layers 212 and the second gate layers 222 may be formed in the sacrificial voids through a thin film deposition process such as chemical vapor deposition (CVD), physical vapor deposition (PVD), atomic layer deposition (ALD), or any combination thereof. By removing a portion of the first gate sacrificial layer 230′, the first gate layer 212 may be formed in the space formed by removing the portion of the first gate sacrificial layer 230′; by removing a portion of the second gate sacrificial layer 240′, the second gate layer 222 may be formed in the space formed by removing the portion of the second gate sacrificial layers 240′.

Each of the first gate layer 212 and the second gate layer 222 may include a conductive material, where the conductive material may include one or more of a conductive metal material and a doped semiconductor material, where the conductive metal material may include, for example, tungsten (W), cobalt (Co), copper (Cu), aluminum (Al), or the like, and the doped semiconductor material may include, for example, doped crystalline silicon or silicide, which is not limited in the present disclosure.

In addition, in some implementations of the present disclosure, after the first gate layers 212 and the second gate layers 222 are formed, the gate line isolation structure 700 may be further formed by filling the gate line slit 701. Specifically, a gate line isolation layer 111 and a gate line filling layer 112 located on a surface of the gate line isolation layer 111 may be formed in a gate line slit 701 by using a thin film deposition process such as chemical vapor deposition (CVD), physical vapor deposition (PVD), atomic layer deposition (ALD), or any combination thereof.

In an example, a material of the gate line isolation layer 111 may include at least one of a high-k dielectric layer and an insulating dielectric material layer such as a silicon oxide layer. In addition, a material of the gate line filling layer 112 may include at least one of a semiconductor material such as polysilicon and an insulating dielectric material layer such as silicon oxide, silicon nitride and silicon oxynitride. In an example, the material of the gate line filling layer 112 may further include a conductive material layer. The present disclosure does not limit the inner filling material of the gate line isolation structure 700.

In addition, as shown in FIG. 15 and FIG. 19 and FIG. 20, after the gate line isolation structures 700, the first gate layers 212 and the second gate layers 222 are formed in the first sub-stacked structure 201′ and the second sub-stacked structure 202′, the first sub-stacked structure 201′ and the second sub-stacked structure 202′ are formed into a stacked structure 200 including the first sub-stacked structures 201 and the second sub-stacked structures 202, where the remaining first gate sacrificial layer 230′ and the remaining second gate sacrificial layer 240′ are formed into first same-layer dielectric layers 230 and second same-layer dielectric layers 240, respectively.

As shown in FIG. 17 to FIG. 20, both the first gate layers 212 and the second gate layers 222 may extend from the first region 11 into the second region 12 along the y direction, and may be respectively connected to the first same-layer dielectric layers 230 and the second same-layer dielectric layers 240 located in the second region 12, where portions of the first gate layers 212 and the second gate layers 222 location in the second region 12 are located at edges of the gate line isolation structure 700. Hereinafter, a contact structure may be formed in a region where the first same-layer dielectric layers 230 and the second same-layer dielectric layers 240 are located, where the contact structure may be connected to one of the plurality of first gate layers 212 and one of the plurality of second gate layers 222. The manufacturing process of the contact structure will be described in detail below with reference to the accompanying drawings.

In addition, as shown in FIG. 16 to FIG. 20, in some implementations of the present disclosure, the first select gate layers 211 located in the first sub-stacked structure 201 and the second select gate layers 221 located in the second sub-stacked structure 202 may also be formed by a method similar to the method for forming the first gate layers 212 and the second gate layers 222, which is not described herein.

### Operation S2

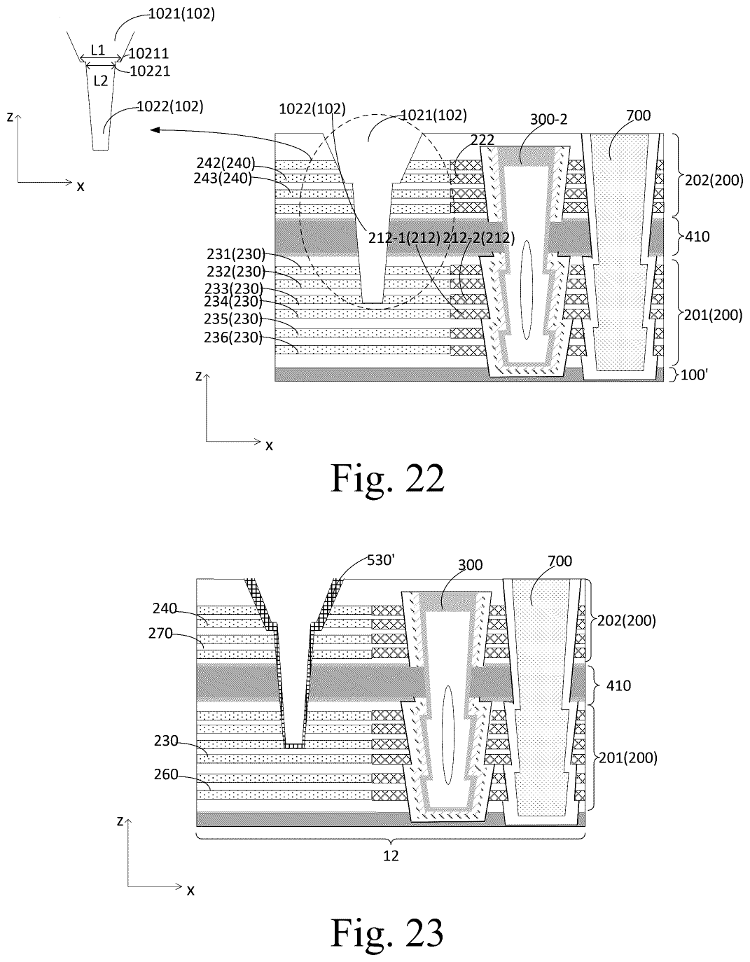

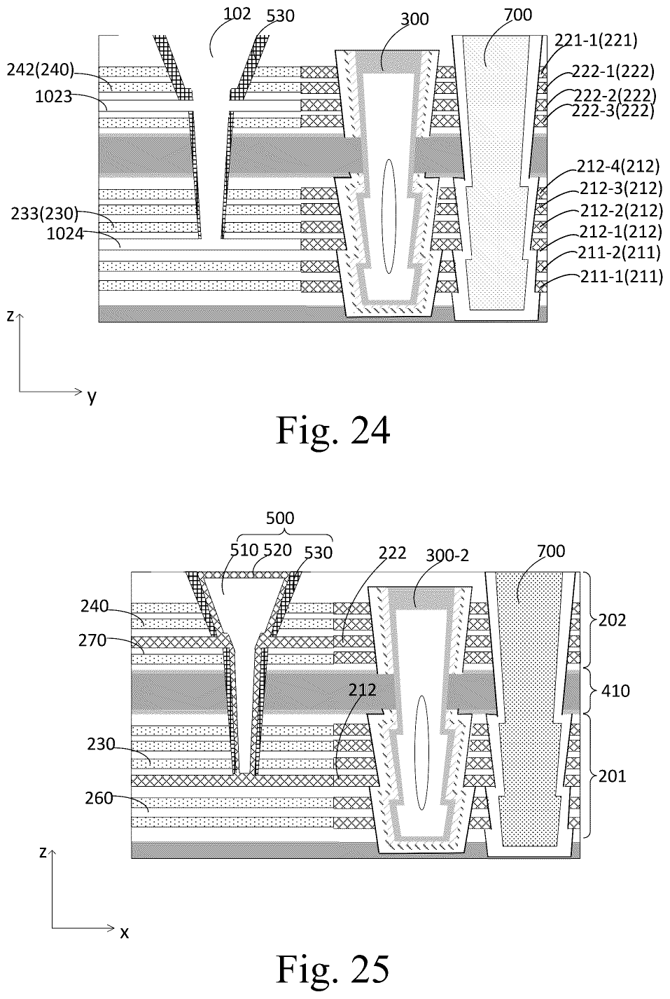

FIG. 21 is a schematic cross-sectional view of a structure formed after forming a first opening 1021 according to a manufacturing method of an implementation of the present disclosure. FIG. 22 is a schematic cross-sectional view of a structure formed after forming a second opening 1022 according to a manufacturing method of an implementation of the present disclosure. FIG. 23 is a schematic cross-sectional view of a structure formed after forming an initial isolation protection layer 530′ according to a manufacturing method of an implementation of the present disclosure. FIG. 24 is a schematic cross-sectional view of a structure formed after forming a third opening 1023 according to a manufacturing method of an implementation of the present disclosure. FIG. 25 is a schematic cross-sectional view of a structure formed after forming a contact structure 500 according to a manufacturing method of an implementation of the present disclosure.

As shown in FIGS. 19, 21-25, operation S2 for forming a contact structure extending in the stacked structure along a first direction and connected to the gate layers of the plurality of sub-stacked structures may, for example, include: forming a contact hole 102 extending in the stacked structure 200 along the z direction and connected to the gate layers of the plurality of sub-stacked structures; and filling the contact hole 102 to form the contact structure 500.

Specifically, as shown in FIG. 19 and FIG. 21 to FIG. 22, in some implementations of the present disclosure, forming the contact hole 102 may include: forming a first opening 1021 extending to first same-layer dielectric layers along the z direction, where the first same-layer dielectric layers are located in a sub-stacked structure farthest from the substrate 100′ among the plurality of sub-stacked structures and are disposed in the same layers as gate layers of the farthest sub-stacked structure; and forming a second opening 1022 communicating with the first opening 1021 via the first opening 1021, where the second opening 1022 extends to second same-layer dielectric layers along the z direction, the second same-layer dielectric layers are located in a sub-stacked structure closest to the farthest sub-stacked structure, where a first end 10211 of the first opening 1021 communicates with a second end 10221 of the second opening 1022, and along a direction intersecting the z direction, a size L1 of the first end 10211 is greater than a size L2 of the second end 10221. It should be noted that “a first same-layer dielectric layer” and “a second same-layer dielectric layers” mentioned above are intended to indicate that the two same-layer dielectric layers are different same-layer dielectric layers, and may also be referred to as “a same-layer dielectric layer” and “another same-layer dielectric layer”, which is not limited in this application.

Specifically, as shown in FIG. 21 and FIG. 22, taking the stacked structure 200 including the first sub-stacked structure 201 and the second sub-stacked structure 202 as an example, a sub-stacked structure farthest from the substrate 100′ among the plurality of sub-stacked structures is the second sub-stacked structure 202, and a sub-stacked structure closest to the sub-stacked structure farthest from the substrate 100′ is the first sub-stacked structure 201. The second sub-stacked structure 202 may include second gate layers 222 and second same-layer dielectric layers 240 disposed in the same layers as the second gate layers 222, for example, a first sub-same-layer dielectric layer 242 disposed in the same layer as a fifth sub-gate layer 222-1, and a second sub-same-layer dielectric layer 243 disposed in the same layer as a sixth sub-gate layer 222-2. In addition, the first sub-stacked structure 201 may include first gate layers 212 and first same-layer dielectric layers 230 disposed in the same layers as the first gate layers 212, for example, a third sub-same-layer dielectric layer 233 disposed in the same layer as the second sub-gate layer 212-2, and a fourth sub-same-layer dielectric layer 234 disposed in the same layer as the first sub-gate layer 212-1.

In an example, by, for example, a dry etching process or a combination of a dry etching process and a wet etching process; or by performing other manufacturing processes such as a patterning process including photolithography, cleaning and chemical mechanical polishing, the first opening 1021 extending to the first sub-same-layer dielectric layer 242 along the z direction is formed. It should be noted that, in the present disclosure, only an example in which the first opening 1021 extends to the first sub-same-layer dielectric layer 242 is used to describe a process of forming the contact hole. In fact, the first opening 1021 may extend to any same-layer dielectric layer in the farthest sub-stacked structure. Similarly, the second opening 1022 may also extend to any same-layer dielectric layer in the sub-stacked structure closest to the farthest sub-stacked structure.

Thereafter, by, for example, a dry etching process or a combination of a dry etching process and a wet etching process; or by performing other manufacturing processes such as a patterning process including photolithography, cleaning and chemical mechanical polishing, the second opening 1022 communicating with the first opening 1021 is formed through the first opening 1021, where the second opening 1022 may extend to the third sub-same-layer dielectric layer 233 along the z direction. The first end 10211 of the first opening 1021 communicates with the second end 10221 of the second opening 1022, and the dimension L1 of the first end 10211 is greater than the dimension L2 of the second end 10221 along a direction intersecting the z direction (e.g., x direction).

In an example, referring to FIG. 22 and FIG. 24, in some implementations of the present disclosure, forming the contact hole 102 may further include: removing the third same-layer dielectric layer adjacent to the first same-layer dielectric layer through the first opening 1021 and the second opening 1022, where the third same-layer dielectric layer is located in the farthest sub-stacked structure and is closer to the substrate 100′ than the first same-layer dielectric layer; and a third opening 1023 formed by removing the third same-layer dielectric layer extending to a gate layer disposed in the same layer as the third same-layer dielectric layer along a direction intersecting the z direction. It should be noted that “a first same-layer dielectric layer” and “a third same-layer dielectric layer” mentioned above are intended to indicate that the two same-layer dielectric layers are different same-layer dielectric layers, and may also be referred to as “a same-layer dielectric layer” and “another same-layer dielectric layer”, which is not limited in this application.

Specifically, by, for example, a dry etching process or a combination of a dry etching process and a wet etching process; or by performing other manufacturing processes such as a patterning process including photolithography, cleaning and chemical mechanical polishing, the second sub-same-layer dielectric layer 243 which is adjacent to the first sub-same-layer dielectric layer 242 along the z direction and closer to the substrate 100′ than the first sub-same-layer dielectric layer 242 is removed via the first opening 1021 and the second opening 1022, thereby forming a third opening 1023 extending to the sixth sub gate layer 222-2 along a direction intersecting with the z direction (e.g., x direction).

Similarly, by, for example, a dry etching process or a combination of a dry etching process and a wet etching process; or by performing other manufacturing processes such as a patterning process including photolithography, cleaning and chemical mechanical polishing, a fourth sub-same-layer dielectric layer 234 which is adjacent to the third sub-same-layer dielectric layer 233 along the z direction and closer to the substrate 100′ than the third sub-same-layer dielectric layer 233 is removed via the first opening 1021 and the second opening 1022, thereby forming a fourth opening 1024 extending to the first sub-gate layer 212-1 along a direction intersecting the z direction (e.g., x direction).

In addition, referring to FIG. 22 to FIG. 24, in some implementations of the present disclosure, before the third opening 1023 is formed, an initial isolation protection layer 530′ may also be formed on inner walls of the first opening 1021 and the second opening 1022.

Specifically, the initial isolation protection layer 530′ may be formed on inner walls of the first opening 1021 and the second opening 1022 through one or more thin film deposition processes which may include, but are not limited to, chemical vapor deposition (CVD), physical vapor deposition (PVD), atomic layer deposition (ALD), or any combination thereof, which is not limited in the present disclosure.

The initial isolation protection layer 530′ may include any suitable insulating dielectric material layer. Exemplarily, the isolation dielectric layer may include an insulating dielectric material layer such as silicon oxide. In the process of forming the third opening 1023 or the fourth opening 1024, the initial isolation protection layer 530′ may protect the first dielectric layers 260 and the second dielectric layers 270 in the stacked structure 200, and the remaining first same-layer dielectric layer 230 and second same-layer dielectric layers 240 that do not need to be removed.

After forming the third opening 1023 and the fourth opening 1024, the remaining initial isolation protection layer 530′ is formed as the isolation protection layer 530. The communicated first opening 1021, second opening 1022, third opening 1023, and fourth opening 1024 are formed as a contact hole 102.

As shown in FIGS. 24-25, after forming the contact hole 102, the contact structure 500 may be formed by filling the contact hole 102. Specifically, the contact structure 500 may be formed in the contact hole 102 by using a thin film deposition process such as chemical vapor deposition (CVD), physical vapor deposition (PVD), atomic layer deposition (ALD), or any combination thereof. The contact structure 500 may include a dielectric filling layer 510 and a conductive structure layer 520 surrounding the dielectric filling layer 510, where the dielectric filling layer 510 may include, for example, a dielectric material such as silicon oxide, silicon nitride, and silicon oxynitride, and the conductive structure layer 520 may include a conductive material, where the conductive material may include one or more of a conductive metal material and a doped semiconductor material, where the conductive metal material may include, for example, tungsten (W), cobalt (Co), copper (Cu), and aluminum (Al), and the doped semiconductor material may include, for example, doped crystalline silicon or a silicide, which is not limited in this application.

In addition, as shown in FIG. 1 and FIG. 25, it should be noted that, in some implementations of the present disclosure, the isolation protection layer 530, the first dielectric layer 260 and the second dielectric layer 270 may be made of the same material, so there is no obvious boundaries between them.

### Operation S3

Referring again to FIG. 1 and FIG. 25, operation S3 for forming a peripheral circuit structure, where at least one of the plurality of select gate layers is connected with the peripheral circuit structure, may, for example, include: providing a peripheral circuit structure 600; and connecting the peripheral circuit structure 600 and the stacked structure 200, and connecting at least one of the plurality of select gate layers with the peripheral circuit structure 600.

In an example, the semiconductor device 1000 may include a memory array, where the memory array may include a channel structure 300 and a contact structure 500. The peripheral circuit structure 600 may include any suitable digital, analog, and/or mixed signal circuit for facilitating operation of a memory array in semiconductor device 1000. For example, the peripheral circuit structure 600 may include one or more of a page buffer, a decoder (e.g., a row decoder and a column decoder), a sense structure (e.g., a bit line sense amplification structure), a driver structure (e.g., a word line driver structure), input/output circuit, a charge pump, a voltage source or generator, a current or voltage reference, any portion of the functional circuits described above (e.g., a sub-circuit), or any active or passive component of the circuit (e.g., a transistor, a diode, a resistor, or a capacitor).

According to some implementations, the peripheral circuit structure 600 may be implemented using, for example, a complementary metal-oxide-semiconductor (CMOS) technology, and is designed according to actual needs, which is not described in detail herein.

In addition, in some implementations of the present disclosure, the memory array and the peripheral circuit structure 600 connected to the memory array may be respectively formed on two different wafers (for example, a memory array wafer and a peripheral circuit wafer), then the peripheral circuit wafer is bonded to the memory array wafer through a process such as wafer bonding, and the peripheral circuit structure 600 and the memory array circuit are connected together through an interconnection layer, an interconnection via, an interconnection line, a connection line, or the like. In some other implementations of the present disclosure, the memory array and the peripheral circuit structure 600 may also be directly formed on the same wafer without forming a connection through the above processes such as wafer bonding, which is not limited in the present disclosure.

In an example, in a case where a bonding process is used, a wafer connection structure 900 penetrating a bonding layer along the z direction may be formed. In an example, the wafer connection structure 900 may include vertical interconnect accesses. By adopting the vertical interconnection access, the input/output transfer speed between the two bonded wafers can be improved, and it is beneficial for the wafer connection structure 900 between the two bonded wafers to connect a connection portion 901 of the contact structure 500 and connection portions (not shown) of the select gate layers.

Therefore, according to the manufacturing method of the semiconductor device provided by at least one implementation of the present disclosure, a stacked structure of the semiconductor device may include a plurality of sub-stacked structures stacked along a first direction, where the contact structure extends along the first direction and is connected to gate layers of the plurality of sub-stacked structures. In addition, the semiconductor device may control different sub-stacked structures to work independently by select gate layers connected to a peripheral circuit. Therefore, this allows the plurality of sub-stacked structures, on the basis of achieving independent operation, to be connected with the peripheral circuit through the same contact structure. The number of contact structures in the semiconductor device is reduced, and the storage density of the semiconductor device is improved, meanwhile the manufacturing process of the contact structure is simplified, and the manufacturing cost of the semiconductor device is reduced.

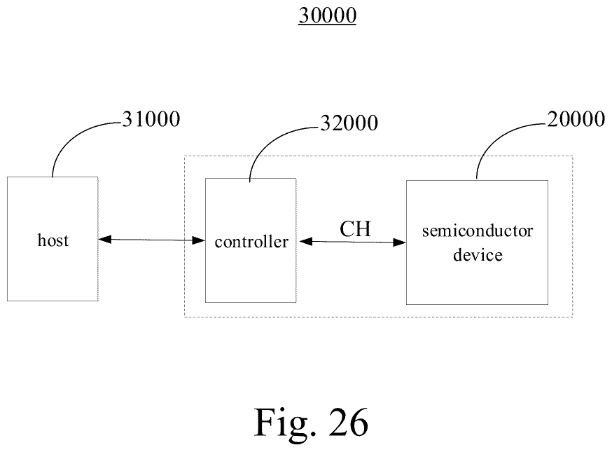

In addition, FIG. 26 is a schematic structural diagram of a memory system 30000 according to an implementation of this application.

As shown in FIG. 26, at least one implementation of another aspect of the present disclosure further provides a memory system 30000. The memory system 30000 may include a semiconductor device 20000 and a controller 32000. The semiconductor device 20000 may be the same as the semiconductor device described in any implementation above, and details are not described herein again. The semiconductor device 20000 may include a two-dimensional semiconductor device or a three-dimensional semiconductor device, or even a part of a two-dimensional semiconductor device or a part of a three-dimensional semiconductor device. The following will describe an example of a three-dimensional semiconductor device.

In an example, the three-dimensional semiconductor device may include at least one of a three-dimensional NAND memory and a three-dimensional NOR memory.

The memory system 30000 may include a semiconductor device 20000 and a controller 32000. The semiconductor device 20000 may be the same as the semiconductor device described in any implementation above, and details are not described herein again. The controller 32000 may control the semiconductor device 20000 through the channel CH, and the semiconductor device 20000 may perform an operation based on control of the controller 32000 in response to a request from the host 31000. The semiconductor device 20000 may receive the command CMD and the address ADDR from the controller 32000 through the channel CH and access a region selected from a memory cell array in response to the address. In other words, the semiconductor device 20000 may perform an internal operation corresponding to the command on the region selected by the address.

In some implementations, the three-dimensional memory system may be implemented as a multimedia card in the form of a universal flash storage (UFS) device, a solid state drive (SSD), an MMC, an eMMC, an RS-MMC and a micro MMC, a secure digital card in the form of an SD, a mini SD and a micro SD, a personal computer memory card international association (PCMCIA) card type storage device, a peripheral component interconnect (PCI) type storage device, a PCI express (PCI-E) type storage device, a compact flash (CF) card, a smart media card or memory stick, or the like. In the memory system provided by the present disclosure, since the semiconductor device provided by the present disclosure is provided, it has the same beneficial effects as the semiconductor device, which will not be repeated here.

Although exemplary fabrication methods and structures for semiconductor devices are described herein, it is understood that one or more features may be omitted, substituted, or added from the structure of the semiconductor device. Moreover, the materials of the layers illustrated are merely exemplary.

The above description is only a preferred implementation of the present disclosure and a description of the applied technical principle. Those skilled in the art should understand that the protection scope involved in the present disclosure is not limited to the technical solution formed by the selected combination of the above technical features, and should also cover other technical solutions formed by any combination of the above technical features or equivalent features thereof without departing from the technical concept. For example, the above features and the technical features having similar functions disclosed in the present disclosure are mutually replaced to form a technical solution.

What is claimed is:

1. A semiconductor device, comprising:
a stacked structure comprising a plurality of sub-stacked structures stacked along a first direction, wherein a sub-stacked structure of the plurality of sub-stacked structures comprises select gate layers and gate layers stacked along the first direction; and
a contact structure extending in the plurality of sub-stacked structures along the first direction and connected to the gate layers of the plurality of sub-stacked structures,
wherein at least one of the select gate layers is connected to a peripheral circuit structure of the semiconductor device.

2. The semiconductor device according to claim 1, wherein:
the plurality of sub-stacked structures comprises a first sub-stacked structure and remaining sub-stacked structures located on a side of the first sub-stacked structure along the first direction, and
the contact structure passes through the remaining sub-stacked structures along the first direction and is connected to gate layers of the first sub-stacked structure.

3. The semiconductor device according to claim 1, wherein:
the gate layers extend in the sub-stacked structure along a direction intersecting the first direction,
the semiconductor device further comprises same-layer dielectric layers disposed in the same layers as the gate layers or the select gate layers, and
the contact structure extends along the first direction and passes through a plurality of the same-layer dielectric layers.

4. The semiconductor device according to claim 1, wherein:
the plurality of sub-stacked structures comprises a first sub-stacked structure and a second sub-stacked structure located on a side of the first sub-stacked structure along the first direction, the semiconductor device further comprises a first semiconductor layer located between the first sub-stacked structure and the second sub-stacked structure along the first direction and extending along a direction intersecting the first direction, and
the select gate layers are located on a side of the gate layers far away from the first semiconductor layer along the first direction.

5. The semiconductor device according to claim 4, further comprising:
a channel structure, comprising:
a channel layer extending along the first direction and connected to the first semiconductor layer; and
a functional layer surrounding the channel layer and comprising a first functional layer and a second functional layer, the first functional layer extending in the first sub-stacked structure along the first direction, and the second functional layer extending in the second sub-stacked structure along the first direction.

6. The semiconductor device according to claim 5, wherein:
the channel layer and the first semiconductor layer have the same doping type, and
a doping concentration of a conductive impurity of the first semiconductor layer is greater than a doping concentration of a conductive impurity of the channel layer.

7. The semiconductor device according to claim 1, further comprising:
second semiconductor layers located on a side of the sub-stacked structures along the first direction and extending along a direction intersecting the first direction,
wherein the second semiconductor layers of the plurality of sub-stacked structures are connected to each other.

8. The semiconductor device according to claim 7, further comprising:
a peripheral circuit located on a side of the stacked structure along the first direction,
wherein the second semiconductor layer is located on a side of the sub-stacked structure far away from the peripheral circuit along the first direction, and
wherein the select gate layers are located on a side of the gate layers far away from the second semiconductor layer along the first direction.

9. The semiconductor device according to claim 7, further comprising:
a channel structure comprising sub-channel structures located in different sub-stacked structures,
wherein the sub-channel structure comprises a sub-channel layer and a sub-functional layer surrounding the sub-channel layer, and
wherein the sub-channel layer extends into the second semiconductor layer along the first direction.

10. The semiconductor device according to claim 9, wherein:
the sub-channel layer and the second semiconductor layer have the same doping type, and
a doping concentration of a conductive impurity of the second semiconductor layer is greater than a doping concentration of a conductive impurity of the sub-channel layer.

11. The semiconductor device according to claim 2, wherein:
the contact structure comprises a first section located in the first sub-stacked structure and a second section located in one of the remaining sub-stacked structures,
the second section comprises a first portion, a second portion and a third portion, the second portion extending along a direction intersecting the first direction and connected to a gate layer of one of the remaining sub-stacked structures, and
the first portion and the third portion are respectively located on two opposite sides of the second portion along the first direction and connected to the second portion.

12. The semiconductor device according to claim 11, wherein:
the second portion is disposed in the same layer as a gate layer of one of the remaining sub-stacked structures; and
along a direction intersecting the first direction, a size of the first portion is greater than a size of the third portion.

13. The semiconductor device according to claim 12, further comprising:
a peripheral circuit located on a side of the stacked structure along the first direction,
wherein the first portion is closer to the peripheral circuit structure than the third portion.

14. The semiconductor device according to claim 12, wherein:
the first portion comprises a first end and a second end opposite to each other along the first direction, and the second end is connected to the second portion, and
along a direction intersecting the first direction, a size of the first end is greater than a size of the second end.

15. The semiconductor device according to claim 14, wherein:
the third portion comprises a third end connected to the second portion, and
along a direction intersecting the first direction, a size of the second end is greater than a size of the third end.

16. The semiconductor device according to claim 2, wherein:
the contact structure comprises a first section located in the first sub-stacked structure and a third section located in one of the remaining sub-stacked structures,
the third section comprises a fourth portion and a fifth portion connected to each other,
the fourth portion passes through the remaining sub-stacked structures along a direction intersecting the first direction and is connected to the first section, and
the fifth portion is connected to gate layers of one of the remaining sub-stacked structures.

17. The semiconductor device according to claim 16, wherein:
the fifth portion has a different thickness along a direction intersecting the first direction, and
the thickness is a dimension of the fifth portion along the first direction.

18. A method of manufacturing a semiconductor device, comprising:
forming a stacked structure, wherein the stacked structure comprises a plurality of sub-stacked structures stacked along a first direction, and a sub-stacked structure of the plurality of sub-stacked structures comprise select gate layers and gate layers stacked along the first direction;
forming a contact structure extending in the stacked structure along the first direction and connected to the gate layers of the plurality of sub-stacked structures; and
forming a peripheral circuit structure, wherein at least one of the select gate layers is connected to the peripheral circuit structure.

19. The method according to claim 18, wherein:
the forming a contact structure extending in the stacked structure along the first direction and connected to the gate layers of the plurality of sub-stacked structures comprises:
forming a contact hole extending in the stacked structure along the first direction and connected to gate layers of the plurality of sub-stacked structures; and
filling the contact hole to form the contact structure,
the method further comprising:
forming the stacked structure on a side of a substrate,
wherein the forming a contact hole extending in the stacked structure along the first direction and connected to the gate layers of the plurality of sub-stacked structures comprises:
forming a first opening extending to first same-layer dielectric layers along the first direction, wherein the first same-layer dielectric layers are located in a sub-stacked structure among the plurality of sub-stacked structures farthest from the substrate and are disposed in the same layers as gate layers of the farthest sub-stacked structure; and
forming a second opening communicating with the first opening via the first opening, wherein the second opening extends to second same-layer dielectric layers along the first direction, the second same-layer dielectric layers are located in a sub-stacked structure closest to the farthest sub-stacked structure, wherein a first end of the first opening communicates with a second end of the second opening, and along a direction intersecting the first direction, a size of the first end is greater than a size of the second end, and
the forming a contact hole extending in the stacked structure along the first direction and connected to the gate layers of the plurality of sub-stacked structures further comprises:
removing third same-layer dielectric layers adjacent to the first same-layer dielectric layers via the first opening and the second opening,
the third same-layer dielectric layers are located in the farthest sub-stacked structure and closer to the substrate than the first same-layer dielectric layers, and
a third opening formed by removing the third same-layer dielectric layers extends, along a direction intersecting the first direction, to gate layers disposed in the same layers as the third same-layer dielectric layers.

20. A memory system, comprising:
at least one semiconductor device, the semiconductor device, comprising:
a stacked structure comprising a plurality of sub-stacked structures stacked along a first direction, wherein a sub-stacked structure of the plurality of sub-stacked structures comprises select gate layers and gate layers stacked along the first direction; and
a contact structure extending in the plurality of sub-stacked structures along the first direction and connected to the gate layers of the plurality of sub-stacked structures,
wherein at least one of the select gate layers is connected to a peripheral circuit structure of the semiconductor device; and
a controller coupled to the semiconductor device and configured to control the semiconductor device to store data.
